(19) United States
(12) Patent Application Publication
(10) Pub. No.: US 2026/0214973 A1
(43) Pub. Date: Jul. 23, 2026

(54) SEMICONDUCTOR DEVICE

(71) Applicant: Samsung Electronics Co., Ltd., Suwon-si (KR)

(72) Inventors: Sanghyun Kim, Suwon-si (KR); In Jun Hwang, Suwon-si (KR)

(21) Appl. No.: 19/282,625

(22) Filed: Jul. 28, 2025

(30) Foreign Application Priority Data
Jan. 20, 2025 (KR) 10-2025-0008166

(51) Int. Cl. H10D 84/80; H10D 1/43; H10D 30/47; H10D 62/85; H10D 64/00

(52) U.S. Cl. CPC H10D 84/817; H10D 1/43; H10D 30/475; H10D 62/8503; H10D 64/111

(57) ABSTRACT

A semiconductor device includes a substrate, a channel layer on the substrate, a barrier layer on the channel layer, a gate electrode on the barrier layer, a source electrode and a drain electrode on opposite lateral sides of the gate electrode and electrically connected to the channel layer, a gate runner, a gate pad, and a resistor in the channel layer, wherein the resistor is electrically connected between the gate pad and the gate runner, or between the gate runner and the gate electrode.

### CROSS-REFERENCE TO RELATED APPLICATION

This application claims priority to and the benefit of Korean Patent Application No. 10-2025-0008166 filed with the Korean Intellectual Property Office on Jan. 20, 2025, the entire contents of which are incorporated herein by reference.

### BACKGROUND

In modern society, semiconductor devices are closely related to everyday life. In particular, the importance of power semiconductor devices used in various fields such as electric vehicles, railways, electric trams in the transportation sector, renewable energy systems like solar and wind power, and mobile devices is gradually increasing. Power semiconductor devices are used to handle high voltage or high current and perform functions such as power conversion and control in large power systems or high-power electronic devices. These devices have the capability and durability to handle high power, manage large currents, and withstand high voltage. For example, power semiconductor devices may handle voltages from hundreds to thousands of volts and currents from tens to thousands of amperes. They may minimize power loss to improve the efficiency of electrical energy. Additionally, power semiconductor devices may operate stably even in environments with high temperatures.

These power semiconductor devices may be classified according to their materials, for example, SiC power semiconductor devices and GaN power semiconductor devices. By using SiC or GaN instead of conventional silicon (Si) to manufacture power semiconductor devices, it is possible to overcome the shortcomings of silicon, which has unstable characteristics at high temperatures. SiC power semiconductor devices are resistant to high temperatures and have low power loss, making them suitable for electric vehicles and renewable energy systems. GaN power semiconductor devices, although requiring high costs, are efficient in terms of speed and may be suitable for fast charging of mobile devices.

### SUMMARY

Some aspects of the present disclosure provide semiconductor devices that include a resistor such that a uniform voltage can be applied to the gate electrodes of a plurality of high electron mobility transistors without increasing the size of the semiconductor devices, and such that the resistance can be customized.

A semiconductor device according to some implementations of the present disclosure includes a substrate, a channel layer on the substrate, a barrier layer on the channel layer, a gate electrode on the barrier layer, a source electrode and a drain electrode on opposite lateral sides of the gate electrode and electrically connected to the channel layer, a gate runner, a gate pad, and a resistor in the channel layer, wherein the resistor is electrically connected between the gate pad and the gate runner, or between the gate runner and the gate electrode.

A semiconductor device according to some implementations of the present disclosure includes a substrate, a channel layer on the substrate, a barrier layer on the channel layer, a gate electrode on the barrier layer, a source electrode and a drain electrode on opposite lateral sides of the gate electrode and electrically connected to the channel layer, a gate runner, a gate pad, and at least one resistor comprising a two-dimensional electron gas, wherein the two-dimensional electron gas is in the channel layer, and wherein the at least one resistor is electrically connected between (i) the gate pad and the gate runner, (ii) the gate runner and the gate electrode, or (i) and (ii).

A semiconductor device according to some implementations of the present disclosure includes a substrate, a high electron mobility transistor on the substrate, a connection wiring on the high electron mobility transistor, a gate runner electrically connected to the high electron mobility transistor through the connection wiring, a gate pad electrically connected to the high electron mobility transistor through the gate runner, and a resistor electrically connected between the gate pad and the gate runner, or between the gate runner and the high electron mobility transistor, wherein the high electron mobility transistor includes a channel layer on the substrate, a barrier layer on the channel layer, a gate electrode on the barrier layer, and a source electrode and a drain electrode on opposite lateral sides of the gate electrode and electrically connected to the channel layer, wherein the resistor is in the channel layer.

Based on the descriptions provided herein, a semiconductor device may be provided that includes a resistor capable of providing a customized resistance while applying a uniform voltage to the gate electrodes of a plurality of high electron mobility transistors, without increasing the size of the semiconductor device.

### BRIEF DESCRIPTION OF THE DRAWINGS

FIG. 1 is a plan view of an example of a semiconductor device.

FIG. 2 is a cross-sectional view taken along line A-A′ of FIG. 1.

FIGS. 3, 4, 5, 6, 7, 8, 9, 10, 11, 12, 13, 14, and 15 are cross-sectional views of examples of semiconductor devices, taken along line B-B′ of FIG. 1.

FIG. 16 is a plan view of an example of a semiconductor device.

FIGS. 17, 18, and 19 are cross-sectional views of examples of semiconductor devices taken along the C-C′ line of FIG. 16.

FIG. 20 is a plan view of an example of a semiconductor device.

FIGS. 21, 22, 23, 24, 25, 26, 27, 28, 29, 30, 31, 32, and 33 are cross-sectional views of examples of semiconductor devices, taken along the D-D′ line of FIG. 20.

FIG. 34 is a plan view of an example of a semiconductor device.

FIGS. 35, 36, and 37 are cross-sectional views of examples of semiconductor devices, taken along line E-E′ of FIG. 34.

### DETAILED DESCRIPTION

Below, with reference to the attached drawings, various examples will be described in detail so that those skilled in the art to which the disclosure pertains may easily implement them. It will be understood that modifications of the disclosed examples are within the scope of the present disclosure.

For clarity of description, description of certain elements less related to the explanation have been omitted, and throughout the specification, the same reference numerals are assigned to the same or similar components.

In addition, the sizes and thicknesses of each component shown in the drawings are illustrated arbitrarily for the sake of convenience in explanation, and the disclosure is not necessarily limited to what is depicted. Thicknesses have been enlarged in the drawings to clearly represent the various layers and regions.

Additionally, when it is stated that a layer, film, region, plate, or similar part is “on” or “above” another part, this includes not only cases where it is directly on top but also where there is another part in between. Conversely, when a part is said to be “directly on” another part, it means there is nothing in between. Furthermore, when it is said to be “on” or “above” a reference part, this does not suggest a direction referenced to gravity.

Furthermore, throughout the specification, when a part is described as “comprising” or “including” a certain component, it means that it may further include other components unless specifically stated otherwise.

Additionally, throughout the entire specification, when referring to “in a plan view,” it means when the target part is viewed from above, and when referring to “in a cross-sectional view,” it means when the cross-section of the target part, cut vertically, is viewed from the side.

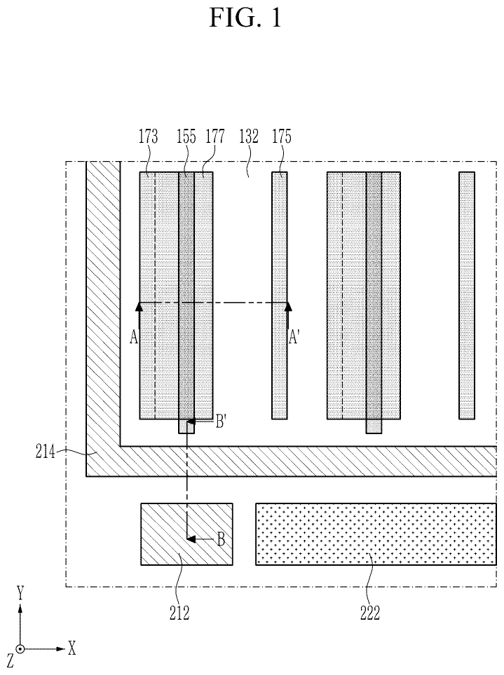

Below, examples of semiconductor devices will be described with reference to FIGS. 1 to 3.

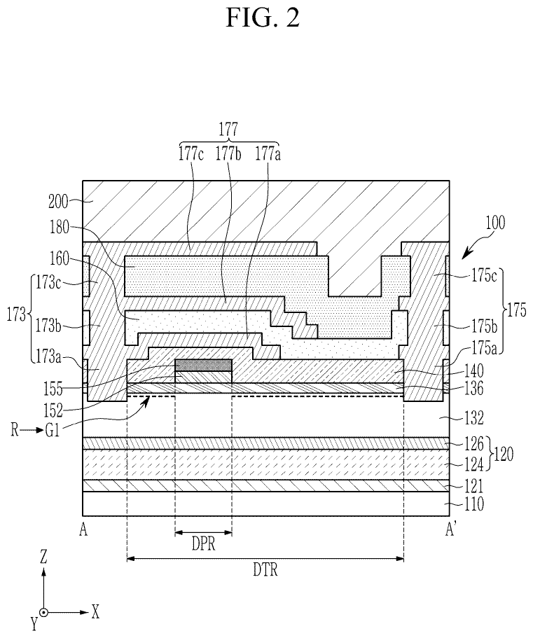

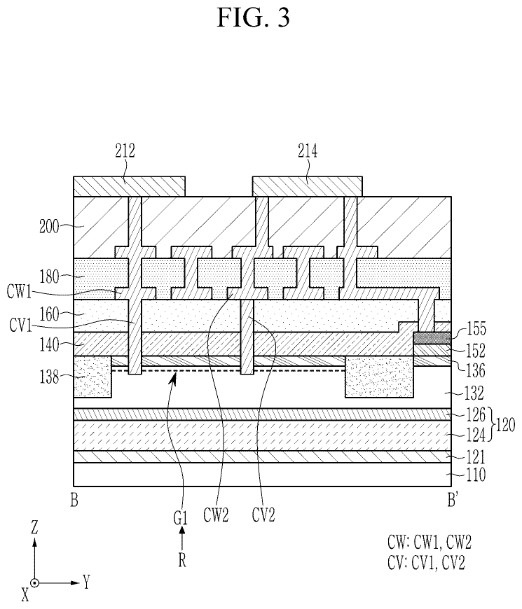

FIG. 1 is a plan view of a semiconductor device. FIG. 2 is a cross-sectional view of the semiconductor device, taken along line A-A′ of FIG. 1. FIG. 3 is a cross-sectional view of the semiconductor device, taken along line B-B′ of FIG. 1. For convenience, FIG. 1 only illustrates the source electrode 173 and field dispersion layer 177, drain electrode 175, gate electrode 155, gate pad 212, gate runner 214, and source pad 222 positioned on the channel layer 132, while other components are omitted.

Referring to FIGS. 1 to 3, the semiconductor device may include a substrate 110, a channel layer 132 on the substrate 110, a barrier layer 136 on the channel layer 132, a gate electrode 155 on the barrier layer 136, a source electrode 173 and a drain electrode 175 located on opposite sides of the gate electrode 155 and connected to the channel layer 132, a gate runner 214 connected to the gate electrode 155, a gate pad 212 connected to the gate runner 214, and a resistor R located in the channel layer 132 and connected (i) between the gate pad 212 and the gate runner 214, and/or (ii) between the gate runner 214 and the gate electrode 155.

The source electrode 173 and drain electrode 175 connected to the gate electrode 155 and the channel layer 132 may form a high electron mobility transistor (HEMT) 100. Although only one or two high electron mobility transistors 100 among a plurality of high electron mobility transistors 100 are shown in FIGS. 1 and 2, this is merely a partial depiction, and more high electron mobility transistors 100 may be located on the substrate 110.

In some implementations, the gate runner 214 may be positioned to surround the edge of the high electron mobility transistor 100 in a plan view. However, arrangements are not limited to this, and the shape in a plan view and arrangement of the gate runner 214 may be variously modified. For example, the gate runner 214 may be connected to the inside of the high electron mobility transistor 100 in a plan view. For example, at least a part of the gate runner 214 may overlap with the high electron mobility transistor 100 in a third direction Z.

In some implementations, the gate pad 212 and the source pad 222 may be located on one side in a second direction Y of the high electron mobility transistor 100 in a plan view. A drain pad may be located on the other side in the second direction Y of the high electron mobility transistor 100 in a plan view. For example, the drain pad may be arranged to face the gate pad 212 and the source pad 222 in a plan view, opposite the gate pad 212 and the source pad 222 across the high electron mobility transistor 100. However, the positional relationship of the gate pad 210, the source pad 222, and the drain pad is not limited to this and may be variously modified.

The resistor R may be located in the same channel layer 132 positioned on the same substrate 110 as the high electron mobility transistor 100. In some implementations, the resistor R may be formed using different parts of the same components as some components of the high electron mobility transistor 100.

The substrate 110 may include semiconductor materials. For example, the substrate 110 may include Si. For example, the substrate 110 may be a p-type Si substrate doped with p-type impurities, but it is not limited thereto. In some implementations, the substrate 110 may be an n-type Si substrate doped with n-type impurities.

The channel layer 132 may be located on the substrate 110. The channel layer 132 is a layer that forms a channel between the source electrode 173 and the drain electrode 175, and a two-dimensional electron gas (2DEG) 134 may be located in the channel layer 132. The two-dimensional electron gas 134 is a charge transport model used in solid-state physics, which may move freely in two dimensions (e.g., the X-Y plane direction) but is tightly confined in the other dimension (e.g., the Z direction), meaning it refers to a group of electrons that are restricted in two dimensions. In other words, the two-dimensional electron gas 134 may exist in the form of a two-dimensional sheet in three-dimensional space. This two-dimensional electron gas 134 mainly appears in semiconductor heterojunction structures and may occur at the interface between the channel layer 132 and the barrier layer 136. For example, the two-dimensional electron gas 134 may occur in the portion of the channel layer 132 adjacent to the barrier layer 136. The channel layer 132 may include one or more materials selected from group III-V materials, such as nitrides containing Al, Ga, In, B, or combinations thereof. The channel layer 132 may be composed of a single layer or multiple layers. The channel layer 132 may be AlₓIn_{y}Ga_{1-x-y}N (0≤x≤1, 0≤y≤1, x+y≤1). For example, the channel layer 132 may include AlN, GaN, InN, InGaN, AlGaN, AlInN, AlInGaN, or combinations thereof. The channel layer 132 may be a doped layer with impurities, or an undoped layer. The thickness of the channel layer 132 may be about several hundred nm or less.

A seed layer 121 and a buffer layer 120 may be located between the substrate 110 and the channel layer 132. The substrate 110, seed layer 121, and buffer layer 120 are layers used for forming the channel layer 132 and may be omitted in some cases. For example, when using a substrate made of GaN as the channel layer 132, at least one of the substrate 110, seed layer 121, and buffer layer 120 may be omitted. Considering that a substrate made of GaN is relatively expensive, a substrate 110 made of Si may be used to grow a channel layer 132 containing GaN. In this case, because the lattice structure of Si and the lattice structure of GaN are different, it may not be easy to grow the channel layer 132 directly on the substrate 110. Accordingly, after first growing the seed layer 121 and buffer layer 120 on the substrate 110, the channel layer 132 may be grown on the buffer layer 120. Additionally, at least one of the substrate 110, seed layer 121, and buffer layer 120 may be removed from the final structure of the semiconductor device after being used in the manufacturing process.

The seed layer 121 may be located directly on the substrate 110. However, it is not limited to this, and an additional layer may be located between the substrate 110 and the seed layer 121. The seed layer 121 acts as a seed for growing the buffer layer 120 and may be composed of a crystal lattice structure that serves as a seed for the buffer layer 120. The buffer layer 120 may be located directly on the seed layer 121. However, it is not limited to this, and an additional layer may be located between the seed layer 121 and the buffer layer 120. The seed layer 121 may include one or more materials selected from among group III-V materials, for example, nitrides containing Al, Ga, In, B, or combinations thereof. The seed layer 121 may be AlₓIn_{y}Ga_{1-x-y}N (0≤x≤1, 0≤y≤1, x+y≤1). For example, the seed layer 121 may include AlN, GaN, InN, InGaN, AlGaN, AlInN, AlInGaN, or combinations thereof.

The buffer layer 120 may be located on the seed layer 121. The buffer layer 120 may be positioned between the seed layer 121 and the channel layer 132. The buffer layer 120 may serve to mitigate the difference in lattice constants and thermal expansion coefficients between the seed layer 121 and the channel layer 132, or it may be a layer that prevents leakage current from flowing through the channel layer 132. The buffer layer 120 may include one or more materials selected from among nitride materials containing group III-V elements, such as Al, Ga, In, B, or combinations thereof. The buffer layer 120 may be AlₓIn_{y}Ga_{1-x-y}N (0≤x≤1, 0≤y≤1, x+y≤1). For example, the buffer layer 120 may include AlN, GaN, InN, InGaN, AlGaN, AlInN, AlInGaN, or combinations thereof.

The buffer layer 120 of the semiconductor device may include a superlattice layer 124 located on the seed layer 121, and a high-resistance layer 126 located on the superlattice layer 124. The superlattice layer 124 and the high-resistance layer 126 may be sequentially positioned on the substrate 110.

The superlattice layer 124 may be located on the seed layer 121. The superlattice layer 124 may be positioned directly on the seed layer 121. However, the positioning is not limited to this, and an additional layer may be positioned between the seed layer 121 and the superlattice layer 124. The superlattice layer 124 alleviates the differences in lattice constants and thermal expansion coefficients between the substrate 110 and the channel layer 132, thereby reducing the tensile stress and compressive stress that occur between the substrate 110 and the channel layer 132. It is a layer intended to relieve stress among all the layers formed by growth in the final structure of a semiconductor device. The superlattice layer 124 may include one or more materials selected from group III-V materials, such as nitrides containing Al, Ga, In, B, or combinations thereof. The superlattice layer 124 may be AlₓIn_{y}Ga_{1-x-y}N (0≤x≤1, 0≤y≤1, x+y≤1). For example, the superlattice layer 124 may include AlN, GaN, InN, InGaN, AlGaN, AlInN, AlInGaN, or combinations thereof.

In some implementations, the superlattice layer 124 may be composed of multiple layers alternately stacked with layers containing different materials. For example, the superlattice layer 124 may have a structure in which layers made of AlGaN and layers made of AlN are repeatedly stacked. For example, AlGaN/AlN/AlGaN/AlN/AlGaN/AlN may be sequentially stacked to form the superlattice layer 124. The number of AlGaN layers and GaN constituting the superlattice layer 124 may be variously changed, and the materials constituting the superlattice layer 124 may be variously changed. As another example, the superlattice layer 124 may have a structure in which layers made of AlGaN and layers made of GaN are repeatedly stacked. That is, AlGaN/GaN/AlGaN/GaN/AlGaN/GaN may be sequentially stacked to form the superlattice layer 124. In some implementations, when the superlattice layer 124 includes GaN, InN, AlGaN, AlInN, InGaN, AlN, AlInGaN, or combinations thereof, the superlattice layer 124 may have n-type semiconductor characteristics where the electron concentration is greater than the hole concentration, but it is not limited thereto.

The high-resistance layer 126 may be located on the superlattice layer 124. The high-resistance layer 126 may be positioned directly on the superlattice layer 124. However, the positioning is not limited to this, and there may be some other layers located between the superlattice layer 124 and the high-resistance layer 126. The high-resistance layer 126 may be located between the superlattice layer 124 and the channel layer 132. By preventing leakage current from flowing through the channel layer 132, the high-resistance layer 126 serves as a layer to prevent the semiconductor device from deteriorating. The high-resistance layer 126 may be made of a low-conductivity material so that the substrate 110 and the channel layer 132 may be electrically insulated from one another. The high-resistance layer 126 may have a resistivity value of 1.0×10⁶ Ω·cm or more. For example, the resistivity value of the high-resistance layer 126 may be 1.0×10¹⁰ Ω·cm or more. As another example, the resistivity value of the high-resistance layer 126 may be 1.0×10¹² Ω·cm or more. The resistivity value may be measured by forming measurement electrodes in the high-resistance layer 126 and allowing current to flow. The high-resistance layer 126 may include one or more materials selected from nitrides containing group III-V materials, such as Al, Ga, In, B, or combinations thereof. The high-resistance layer 126 may be AlₓIn_{y}Ga_{1-x-y}N (0≤x≤1, 0≤y≤1, x+y≤1). For example, the high-resistance layer 126 may include AlN, GaN, InN, InGaN, AlGaN, AlInN, AlInGaN, or combinations thereof. The high-resistance layer 126 may be composed of a single layer or multiple layers. In some implementations, when the high-resistance layer 126 includes GaN, InN, AlGaN, AlInN, InGaN, AlN, AlInGaN, or combinations thereof, the high-resistance layer 126 may have n-type semiconductor characteristics where the electron concentration is greater than the hole concentration, but it is not limited to this.

The barrier layer 136 may be located on the channel layer 132. The barrier layer 136 may be positioned directly on the channel layer 132. However, the arrangement is not limited thereto, and other layer(s) may be positioned between the channel layer 132 and the barrier layer 136. The region of the channel layer 132 that overlaps with the barrier layer 136 between the source electrode 173 and the drain electrode 175 may become the drift region DTR. The drift region DTR may be located between the source electrode 173 and the drain electrode 175. The drift region DTR may refer to the region where carriers move when a potential difference occurs between the source electrode 173 and the drain electrode 175.

The semiconductor device may be turned on/off depending on whether a voltage is applied to the gate electrode 155 and/or the magnitude of the voltage applied to the gate electrode 155. Accordingly, the movement of carriers in the drift region DTR may occur or be blocked.

The barrier layer 136 may include one or more materials selected from nitrides containing Group III-V materials, such as Al, Ga, In, B, or combinations thereof. The barrier layer 136 may be AlₓIn_{y}Ga_{1-x-y}N (0≤x≤1, 0≤y≤1, x+y≤1). The barrier layer 136 may include GaN, InN, AlGaN, AlInN, InGaN, AlN, AlInGaN, or combinations thereof. The energy band gap of the barrier layer 136 may be adjusted by the composition ratio of Al and/or In.

The barrier layer 136 may include a semiconductor material with different properties from the channel layer 132. The barrier layer 136 may differ from the channel layer 132 in terms of polarization characteristics, energy band gap, or lattice constant, among at least one of these. For example, the barrier layer 136 may include a material with a different energy band gap than the channel layer 132. In this case, the barrier layer 136 may have a higher energy band gap than the channel layer 132 and may also have a higher electrical polarization rate than the channel layer 132. Due to this barrier layer 136, a two-dimensional electron gas 134 may be induced in the channel layer 132, which has a relatively low electrical polarization rate. In this context, the barrier layer 136 may also be referred to as a channel supply layer or a two-dimensional electron gas supply layer. The two-dimensional electron gas 134 may be formed in a portion of the channel layer 132 located below the interface between the channel layer 132 and the barrier layer 136. The two-dimensional electron gas 134 may have very high electron mobility.

The barrier layer 136 may be composed of a single layer or multiple layers. When the barrier layer 136 is composed of multiple layers, the material of each layer constituting the multiple layers may have a different energy band gap. In this case, the various layers constituting the barrier layer 136 may be arranged such that the energy band gap increases as they get closer to the channel layer 132.

The gate electrode 155 may be located on the barrier layer 136. The gate electrode 155 may overlap with some regions of the barrier layer 136. The gate electrode 155 may overlap with a portion of the drift region DTR of the channel layer 132. The gate electrode 155 may be positioned between the source electrode 173 and the drain electrode 175. The gate electrode 155 may be spaced apart from the source electrode 173 and the drain electrode 175 in a first direction X. The first direction X may be a direction parallel to the upper surface of the channel layer 132. The gate electrode 155 may be located approximately at the center between the source electrode 173 and the drain electrode 175. For example, the distance in the first direction X between the gate electrode 155 and the source electrode 173 may be similar to the distance in the first direction X between the gate electrode 155 and the drain electrode 175. However, the position of the gate electrode 155 is not limited to this and may be varied in various ways. For example, the gate electrode 155 may be positioned closer to the source electrode 173 than to the drain electrode 175. For example, the distance between the gate electrode 155 and the source electrode 173 may be smaller than the distance between the gate electrode 155 and the drain electrode 175.

The gate electrode 155 may extend in the second direction Y different from the first direction X on a plan view. The second direction Y may be a direction parallel to the upper surface of the channel layer 132 and may intersect with the first direction X. For example, the second direction Y may be a direction perpendicular to the first direction X. The gate electrode 155 may have a rod, bar, or rectangle shape extending along the second direction Y.

The gate electrode 155 may include a conductive material. For example, the gate electrode 155 may include metal, metal alloy, conductive metal nitride, metal silicide, doped semiconductor material, conductive metal oxide, or conductive metal oxynitride, among other possibilities. For example, the gate electrode 155 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but is not limited thereto. The gate electrode 155 may be formed as a single layer or a multilayer.

In some implementations, the semiconductor device may further include a hard mask layer positioned on the gate electrode 155. The hard mask layer may be a hard mask used when patterning the gate electrode material layer or the gate semiconductor material layer during the formation of the gate electrode 155. However, the hard mask layer may be removed depending on the etching conditions of the gate semiconductor material layer or the cleaning conditions after etching. For example, the hard mask layer may include silicon oxide, silicon nitride, silicon oxynitride, or a combination thereof.

The gate electrode 155 may have substantially the same shape in a plan view as the gate semiconductor layer 152. The gate electrode 155 may have substantially the same width as the gate semiconductor layer 152.

The gate semiconductor layer 152 may be positioned between the source electrode 173 and the drain electrode 175. The gate semiconductor layer 152 may be spaced apart from the source electrode 173 and the drain electrode 175. The gate semiconductor layer 152 may be located approximately at the center between the source electrode 173 and the drain electrode 175. For example, the distance in the first direction X between the gate semiconductor layer 152 and the source electrode 173 may be similar to the distance in the first direction X between the gate semiconductor layer 152 and the drain electrode 175. However, the position of the gate semiconductor layer 152 is not limited to this and may be variously changed. For example, the gate semiconductor layer 152 may be positioned closer to the source electrode 173 than to the drain electrode 175. For example, the distance between the gate semiconductor layer 152 and the source electrode 173 may be smaller than the distance between the gate semiconductor layer 152 and the drain electrode 175.

The gate semiconductor layer 152 may include one or more materials selected from nitrides containing at least one of Group III-V materials, such as Al, Ga, In, and B. The gate semiconductor layer 152 may be AlₓIn_{y}Ga_{1-x-y}N (0≤x≤1, 0≤y≤1, x+y≤1). For example, the gate semiconductor layer 152 may include at least one of AlN, GaN, InN, InGaN, AlGaN, AlInN, and AlInGaN. The gate semiconductor layer 152 may include a material having an energy band gap different from that of the barrier layer 136. For example, the gate semiconductor layer 152 may include GaN, and the barrier layer 136 may include AlGaN. The gate semiconductor layer 152 may be doped with a impurity. In this case, the impurity doped into the gate semiconductor layer 152 may be a p-type impurity capable of providing holes. For example, the gate semiconductor layer 152 may include GaN doped with a p-type impurity. For example, the gate semiconductor layer 152 may be formed of a p-GaN layer. However, the material is not limited thereto, and the gate semiconductor layer 152 may also be a p-AlGaN layer. For example, the impurity doped into the gate semiconductor layer 152 may be magnesium (Mg). The gate semiconductor layer 152 may be formed as a single layer or a multilayer.

A depletion region DPR may be formed in the channel layer 132 by the gate semiconductor layer 152. The depletion region DPR may be located in the drift region DTR and may have a narrower width than the drift region DTR. As the gate semiconductor layer 152, which includes a p-type impurity capable of providing holes, is positioned on the barrier layer 136, electrons in the region of the channel layer 132 overlapping with the gate semiconductor layer 152 may be repelled, thereby forming a depletion region DPR. The depletion region DPR may be a region of the channel path in the channel layer 132 where the two-dimensional electron gas 134 is not formed or has a lower electron concentration than the remaining regions. For example, the depletion region DPR may refer to a region in the drift region DTR where the flow of the two-dimensional electron gas 134 is interrupted. As the depletion region DPR occurs, current may not flow between the source electrode 173 and the drain electrode 175, and the channel path may be blocked. Accordingly, the high electron mobility transistor 100 of the semiconductor device may have a normally off characteristic.

In other words, the high electron mobility transistor 100 of the semiconductor device may be a normally-off high electron mobility transistor. In the normal state where no voltage is applied to the gate electrode 155, the depletion region DPR exists, and the high electron mobility transistor 100 may be in the off state. When a voltage equal to or greater than the threshold voltage is applied to the gate electrode 155, at least a part of the depletion region DPR disappears, and the two-dimensional electron gas 134 in the drift region DTR may remain unbroken and connected. For example, a two-dimensional electron gas 134 connected along the first direction X in the channel path between the source electrode 173 and the drain electrode 175 may be formed, and the high electron mobility transistor 100 may be in the on state. In summary, in some implementations, the high electron mobility transistor 100 of the semiconductor device may include semiconductor layers with different electrical polarization characteristics, and the semiconductor layer with a relatively large polarization rate may induce a two-dimensional electron gas 134 in another semiconductor layer that is heterojunctioned with it. This two-dimensional electron gas 134 may be used as a channel between the source electrode 173 and the drain electrode 175, and the continuation or interruption of the flow of this two-dimensional electron gas 134 may be controlled by the bias voltage applied to the gate electrode 155. In the gate-off state, the flow of the two-dimensional electron gas 134 is blocked, and no current may flow between the source electrode 173 and the drain electrode 175. In the gate-on state, as the flow of the two-dimensional electron gas 134 continues, current may flow between the source electrode 173 and the drain electrode 175.

It was explained above that the high electron mobility transistor 100 of the semiconductor device is a normally-off high electron mobility transistor, but the transistor type is not limited to this. For example, the high electron mobility transistor 100 of the semiconductor device may be a normally-on high electron mobility transistor. In the case of a normally-on high electron mobility transistor, the gate semiconductor layer 152 may be omitted, and accordingly, the gate electrode 155 may be located directly on the barrier layer 136. For example, the gate electrode 155 may contact the barrier layer 136. In this structure, the two-dimensional electron gas 134 may be used as a channel in a state where no voltage is applied to the gate electrode 155, and a current flow may occur between the source electrode 173 and the drain electrode 175. Additionally, when a negative voltage is applied to the gate electrode 155, a depletion region DPR may occur, interrupting the flow of the two-dimensional electron gas 134 below the gate electrode 155.

The seed layer 121, buffer layer 120, channel layer 132, barrier layer 136, and gate semiconductor layer 152 described above may be sequentially stacked on the substrate 110. In the semiconductor device, at least one of the seed layer 121, buffer layer 120, channel layer 132, barrier layer 136, and gate semiconductor layer 152 may be omitted. These seed layer 121, buffer layer 120, channel layer 132, barrier layer 136, and gate semiconductor layer 152 may be made of the same base semiconductor material, and the material composition ratio of each layer may vary depending on the role of each layer, the performance required by the semiconductor device, and other factors.

The semiconductor device may further include a first protective layer 140 positioned on the barrier layer 136, the gate semiconductor layer 152, and the gate electrode 155. The first protective layer 140 may cover the upper surface of the barrier layer 136, cover the side surfaces of the gate semiconductor layer 152, and cover the upper surface and side surfaces of the gate electrode 155. The first protective layer 140 may be in contact with the barrier layer 136, the gate semiconductor layer 152, and the gate electrode 155. The barrier layer 136, the gate semiconductor layer 152, and the gate electrode 155, among others, may be protected by the first protective layer 140 and may be isolated from other components. The first protective layer 140 may include an insulating material. For example, the first protective layer 140 may include oxides such as SiO₂ or Al₂O₃. As another example, the first protective layer 140 may include nitrides such as SiN or oxynitrides such as SiON. The first protective layer 140 may be formed as a single layer or multiple layers.

The source electrode 173 and the drain electrode 175 may be located on the channel layer 132. The source electrode 173 and the drain electrode 175 may be spaced apart from each other, and the gate electrode 155 and the gate semiconductor layer 152 may be positioned between the source electrode 173 and the drain electrode 175. The gate electrode 155 and the gate semiconductor layer 152 are spaced apart from the source electrode 173 and the drain electrode 175. The source electrode 173 may be electrically connected to the channel layer 132 on one side of the gate electrode 155. The drain electrode 175 may be electrically connected to the channel layer 132 on the other side of the gate electrode 155. The source electrode 173 and the drain electrode 175 may be located outside the drift region DTR of the channel layer 132. The interface between the source electrode 173 and the channel layer 132 may be one edge of the drift region DTR. Similarly, the interface between the drain electrode 175 and the channel layer 132 may be the other edge of the drift region DTR. However, the arrangement is not limited to this, and the source electrode 173 and the drain electrode 175 may not be located outside the drift region DTR of the channel layer 132. In this case, the channel layer 132 may not be recessed, and the source electrode 173 and the drain electrode 175 may be positioned on the upper surface of the channel layer 132. As another example, the barrier layer 136 may not be penetrated, and a portion of the barrier layer 136 may be recessed, allowing the source electrode 173 and the drain electrode 175 to be positioned on the upper surface of the barrier layer 136. The bottom surfaces of the source electrode 173 and the drain electrode 175 may be in contact with the upper surface of the barrier layer 136. The portions of the channel layer 132 or the barrier layer 136 that contact the source electrode 173 and the drain electrode 175 may be highly doped. In this case, carriers that have passed through the two-dimensional electron gas 134 may be transferred to the source electrode 173 and the drain electrode 175 through the highly doped portions of the channel layer 132 or the barrier layer 136. The source electrode 173 and the drain electrode 175 may not be in direct contact with the two-dimensional electron gas 134 in the horizontal direction. The horizontal direction may refer to a direction parallel to the upper surface of the channel layer 132 or the barrier layer 136, e.g., the X direction, the Y direction, or a direction parallel thereto.

The source electrode 173 and the drain electrode 175 may be located on the first protective layer 140. A trench that penetrates the first protective layer 140 and the barrier layer 136 and recesses the upper surface of the channel layer 132 may be positioned spaced apart from each other on opposite sides of the gate electrode 155. The source electrode 173 and the drain electrode 175 may each be located in the trenches positioned on opposite sides of the gate electrode 155. The source electrode 173 and the drain electrode 175 may be formed to fill the trench. In the trench, the source electrode 173 and the drain electrode 175 may contact the channel layer 132 and the barrier layer 136. The channel layer 132 may form the bottom and sidewalls of the trench, and the barrier layer 136 may form the sidewalls of the trench. Therefore, the source electrode 173 and the drain electrode 175 may contact the upper surface and the side surfaces of the channel layer 132. Additionally, the source electrode 173 and the drain electrode 175 may contact the side surfaces of the barrier layer 136. In other words, the source electrode 173 and the drain electrode 175 may cover the side surfaces of the channel layer 132 and the barrier layer 136. The upper surfaces of the source electrode 173 and the drain electrode 175 may protrude beyond the upper surface of the first protective layer 140. In some implementations, at least one of the source electrode 173 or the drain electrode 175 may cover at least a portion of the upper surface of the first protective layer 140.

The source electrode 173 and the drain electrode 175 may be spaced apart in the first direction X. The source electrode 173 and the drain electrode 175 may extend in the second direction Y in a plan view. The source electrode 173 and the drain electrode 175 may extend in a direction parallel to the gate electrode 155.

The source electrode 173 and the drain electrode 175 may include conductive materials. For example, the source electrode 173 and the drain electrode 175 may include metals, metal alloys, conductive metal nitrides, metal silicides, doped semiconductor materials, conductive metal oxides, or conductive metal oxynitrides. For example, the source electrode 173 and the drain electrode 175 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are not limited to these. The source electrode 173 and the drain electrode 175 may be formed as a single layer or multiple layers. The source electrode 173 and the drain electrode 175 may make ohmic contact with the channel layer 132. The regions in the channel layer 132 that contact the source electrode 173 and the drain electrode 175 may be doped at a relatively high concentration compared to other regions.

The field dispersion layer 177 may be located between the source electrode 173 and the drain electrode 175. The field dispersion layer 177 may overlap with the gate electrode 155 in the third direction Z. The gate electrode 155 may be covered by the field dispersion layer 177. The field dispersion layer 177 may be electrically connected to the source electrode 173. The field dispersion layer 177 may include the same material as the source electrode 173 and may be located in the same layer as the source electrode 173.

However, the configuration of the field dispersion layer 177, and the field dispersion layer 177 may be a separate component separated from the source electrode 173. Additionally, the field dispersion layer 177 may be located in a different layer from the source electrode 173 and may be formed in a different process. In some cases, the field dispersion layer 177 may be electrically connected to the gate electrode 155. For example, an opening overlapping the gate electrode 155 may be formed in the first protective layer 140, and the field dispersion layer 177 may be connected to the gate electrode 155 through the opening. In this case, the field dispersion layer 177 may not be connected to the source electrode 173.

The field dispersion layer 177 may serve to disperse the electric field concentrated around the gate electrode 155. When a high voltage is applied to the drain electrode 175 in the gate-off state, the electric field may become concentrated around the gate electrode 155. If the electric field is concentrated on the gate electrode 155, leakage current may increase, and breakdown voltage may decrease. The field dispersion layer 177 may disperse the electric field concentrated around the gate electrode 155, thereby reducing leakage current and increasing breakdown voltage.

As shown in FIG. 2, the source electrode 173 and the drain electrode 175 may be composed of triple layers. For example, the source electrode 173 may include a plurality of source electrodes 173a, 173b, 173c sequentially stacked in the third direction Z on the channel layer 132, and the drain electrode 175 may also include a plurality of drain electrodes 175a, 175b, 175c sequentially stacked in the third direction Z on the channel layer 132. The plurality of source electrodes 173a, 173b, 173c may include a first source electrode 173a, a second source electrode 173b, and a third source electrode 173c, and the plurality of drain electrodes 175a, 175b, 175c may include a first drain electrode 175a, a second drain electrode 175b, and a third drain electrode 175c. However, the electrode configuration is not limited thereto, and the source electrode 173 and drain electrode 175 may be composed of a single layer or a double layer, and may include four or more layers.

In FIG. 2, the semiconductor device is shown to include three field dispersion layers 177a, 177b, 177c, but the number of field dispersion layers 177 is not limited to this. For example, the field dispersion layer 177 may include a plurality of field dispersion layers 177a, 177b, 177c that overlap with the gate electrode 155 in the third direction Z. Each of the plurality of field dispersion layers 177a, 177b, 177c may be located between a plurality of pairs of source electrodes 173 and drain electrodes 175. Each of the plurality of field dispersion layers 177a, 177b, 177c may be electrically connected to a plurality of source electrodes 173a, 173b, 173c. Each of the plurality of field dispersion layers 177a, 177b, 177c may be integrally formed with each of the plurality of source electrodes 173a, 173b, 173c, but is not necessarily limited to this.

For example, multiple field dispersion layers 177a, 177b, 177c may include a first field dispersion layer 177a, a second field dispersion layer 177b, and a third field dispersion layer 177c. The first field dispersion layer 177a is formed simultaneously in the same process as the first source electrode 173a, the second field dispersion layer 177b is formed simultaneously in the same process as the second source electrode 173b, and the third field dispersion layer 177c is formed simultaneously in the same process as the third source electrode 173c. The boundary between the first field dispersion layer 177a and the first source electrode 173a may not be clear, and the first field dispersion layer 177a may be integrally formed with the first source electrode 173a. The boundary between the second field dispersion layer 177b and the second source electrode 173b may not be clear, and the second field dispersion layer 177b may be integrally formed with the second source electrode 173b. The boundary between the third field dispersion layer 177c and the third source electrode 173c may not be clear, and the third field dispersion layer 177c may be integrally formed with the third source electrode 173c.

Among the multiple field dispersion layers 177a, 177b, 177c, the second field dispersion layer 177b may entirely cover the first field dispersion layer 177a located between the second field dispersion layer 177b and the gate electrode 155. The width of the second field dispersion layer 177b may be greater than the width of the first field dispersion layer 177a. The width of the first field dispersion layer 177a and the width of the second field dispersion layer 177b may refer to the length in the first direction X extending from the source electrode 173 to the drain electrode 175.

Among the multiple field dispersion layers 177a, 177b, 177c, the third field dispersion layer 177c may entirely cover the first field dispersion layer 177a, which is located between the third field dispersion layer 177c and the gate electrode 155. The third field dispersion layer 177c may be the uppermost field dispersion layer among the multiple field dispersion layers 177a, 177b, 177c. The width of the third field dispersion layer 177c may be greater than the width of the first field dispersion layer 177a. The width of the third field dispersion layer 177c may be equal to or shorter than the width of the second field dispersion layer 177b. The widths of the first field dispersion layer 177a, the second field dispersion layer 177b, and the third field dispersion layer 177c may refer to the length in the first direction X, which extends from the source electrode 173 to the drain electrode 175.

The semiconductor device may further include a second protective layer 160 and a third protective layer 180 positioned between a plurality of field dispersion layers 177a, 177b, 177c. The first field dispersion layer 177a and the second field dispersion layer 177b are spaced apart from each other in a third direction Z by the second protective layer 160, and the second field dispersion layer 177b and the third field dispersion layer 177c may be spaced apart from each other in the third direction Z by the third protective layer 180. The second protective layer 160 may be positioned between the first field dispersion layer 177a and the second field dispersion layer 177b. The third protective layer 180 may be positioned between the second field dispersion layer 177b and the third field dispersion layer 177c.

The second protective layer 160 may be located on the first protective layer 140 and the first field dispersion layer 177a. The second protective layer 160 may cover the upper surface of the first protective layer 140. The second protective layer 160 may cover the upper surface and side surface of the first field dispersion layer 177a. The second protective layer 160 may cover the side surface of the first drain electrode 175a. In some implementations, the second protective layer 160 may cover at least a portion of the upper surface of at least one of the first source electrode 173a and the first drain electrode 175a.

The second source electrode 173b, the second field dispersion layer 177b, and the second drain electrode 175b may be located on the second protective layer 160. Each of the second source electrode 173b and the second drain electrode 175b may penetrate the second protective layer 160 to contact the upper surfaces of the first source electrode 173a and the first drain electrode 175a. The second field dispersion layer 177b may cover at least a portion of the upper surface of the second protective layer 160. In some cases, at least one of the second source electrode 173b and the second drain electrode 175b may cover at least a portion of the upper surface of the second protective layer 160.

The second protective layer 160 may include an insulating material. For example, the second protective layer 160 may include oxides such as SiO₂ or Al₂O₃. As another example, the second protective layer 160 may include nitrides such as SiN or oxynitrides such as SiON. The second protective layer 160 may be composed of a single layer or multiple layers. The second protective layer 160 may include the same material as the first protective layer 140, or it may include a different material.

The third protective layer 180 may be positioned on the second protective layer 160 and the second field dispersion layer 177b. The third protective layer 180 may cover the upper surface of the second protective layer 160. The third protective layer 180 may cover the upper surface and the side surface of the second field dispersion layer 177b. The third protective layer 180 may cover the side surface of the second drain electrode 175b. In some cases, the third protective layer 180 may cover at least a portion of the upper surface of at least one of the second source electrode 173b and the second drain electrode 175b.

The third source electrode 173c, the third field dispersion layer 177c, and the third drain electrode 175c may be positioned on the third protective layer 180. Each of the third source electrode 173c and the third drain electrode 175c may penetrate the third protective layer 180 and contact the upper surface of the second source electrode 173b and the second drain electrode 175b. The third field dispersion layer 177c may cover at least a portion of the upper surface of the third protective layer 180. In some cases, at least one of the third source electrode 173c and the third drain electrode 175c may cover at least a portion of the upper surface of the third protective layer 180.

The third protective layer 180 may include an insulating material. For example, the third protective layer 180 may include oxides such as SiO₂ or Al₂O₃. As another example, the third protective layer 180 may include nitrides such as SiN or oxynitrides such as SiON. The third protective layer 180 may be composed of a single layer or multiple layers. The third protective layer 180 may include the same material as at least some of the first protective layer 140 and the second protective layer 160, or it may include different materials.

The semiconductor device may further include a fourth protective layer 200 positioned on a plurality of field dispersion layers 177a, 177b, 177c. The fourth protective layer 200 may be located on the third protective layer 180 and the third field dispersion layer 177c. The fourth protective layer 200 may cover the upper surface of the third protective layer 180. The fourth protective layer 200 may cover the side surface of the third field dispersion layer 177c. The fourth protective layer 200 may cover the upper surfaces of the third source electrode 173c and the third drain electrode 175c.

The fourth protective layer 200 may include an insulating material. For example, the fourth protective layer 200 may include oxides such as SiO₂ or Al₂O₃. As another example, the fourth protective layer 200 may include nitrides such as SiN or oxynitrides such as SiON. The fourth protective layer 200 may be composed of a single layer or multiple layers. The fourth protective layer 200 may include the same material as at least some of the first protective layer 140, second protective layer 160, and third protective layer 180, or it may include different materials.

In some implementations, at least some components included in the high electron mobility transistor 100 may be extended and located in the peripheral region of the high electron mobility transistor 100. Here, the peripheral region of the high electron mobility transistor 100 may refer to the region surrounding the edge of the high electron mobility transistor 100. For example, the channel layer 132, barrier layer 136, and multiple protective layers 140, 160, 180, 200 may be further positioned in the peripheral region of the high electron mobility transistor 100. For example, the channel layer 132, barrier layer 136, and multiple protective layers 140, 160, 180, 200 may be entirely located on the substrate 110. The semiconductor device may include a connection wiring CW positioned on the channel layer 132. The connection wiring CW may connect the gate electrode 155 of the high electron mobility transistor 100 with the gate runner 214, and connect the gate runner 214 with the gate pad 212 (e.g., through a resistor R).

In some implementations, the connection wiring CW may be composed of multiple layers. For example, the connection wiring CW may include a first layer located on the first protective layer 140, a second layer located on the second protective layer 160, and a third layer located on the third protective layer 180. In some implementations, the connection wiring CW may be composed of three layers, but it is not limited to this. The number of layers of the connection wiring CW may be varied.

In some implementations, the connection wiring CW may be formed simultaneously in the same process as the source electrode 173, field dispersion layer 177, and drain electrode 175. The first layer of the connection wiring CW may be located on the same layer as the first source electrode 173a, first field dispersion layer 177a, and first drain electrode 175a, and may include the same material. The first layer of the connection wiring CW may be formed simultaneously in the same process as the first source electrode 173a, first field dispersion layer 177a, and first drain electrode 175a. The second layer of the connection wiring CW may be located on the same layer as the second source electrode 173b, second field dispersion layer 177b, and second drain electrode 175b, and may include the same material. The second layer of the connection wiring CW may be formed simultaneously in the same process as the second source electrode 173b, second field dispersion layer 177b, and second drain electrode 175b. The third layer of the connection wiring CW may be located on the same layer as the third source electrode 173c, third field dispersion layer 177c, and third drain electrode 175c, and may include the same material. The third layer of the connection wiring CW may be formed simultaneously in the same process as the third source electrode 173c, third field dispersion layer 177c, and third drain electrode 175c.

In some implementations, a fourth protective layer 200 may be positioned on the third layer of the connecting wiring CW. The connecting wiring CW may be covered by the fourth protective layer 200.

In some implementations, the gate pad 212 and the gate runner 214 may be located on the fourth protective layer 200. For example, the gate runner 214 may be located on the same layer as the gate pad 212. In FIG. 3, the gate pad 212 and the gate runner 214 are shown as being positioned on the topmost layer of the connection wiring CW, but the positioning is not limited thereto. For example, the connection wiring CW may further include a fourth layer located on the fourth protective layer 200, and the fourth layer of the connection wiring CW may be the same layer as the gate pad 212 and the gate runner 214. For example, the fourth layer of the connection wiring CW may be formed simultaneously in the same process as the gate pad 212 and the gate runner 214.

The semiconductor device may include a connection via CV that connects the connection wiring CW in a third direction Z. The connection via CV may connect between connection wirings CW located on different layers. The connection via CV may connect between the connection wiring CW and the gate electrode 155. The connection via CV may connect between the connection wiring CW and the gate pad 212. The connection via CV may connect between the connection wiring CW and the gate runner 214.

Accordingly, the connection wiring CW and connection via CV may connect between the gate electrode 155 and the gate runner 214. The connection wiring CW and connection via CV may connect between the gate runner 214 and the gate pad 212.

In some implementations, the connection wiring CW and the connection via CV may include the same material as the source electrode 173, the field dispersion layer 177, and the drain electrode 175.

In some implementations, at least a portion of the gate pad 212 and gate runner 214 may include a material different from the connection wiring CW and connection via CV.

In some implementations, a resistor R may be connected between the gate pad 212 and the gate runner 214. The connection wiring CW and connection via CV may include a first connection wiring CW1 and a first connection via CV1 that connect the gate pad 212 and the resistor R. The connection wiring CW and connection via CV may include a second connection wiring CW2 and a second connection via CV2 that connect the gate runner 214 and the resistor R.

In some implementations, the first connection via CV1 and the second connection via CV2 may be connected to the channel layer 132. The first connection via CV1 and the second connection via CV2 may be connected to the channel layer 132 through the barrier layer 136. The lower surface and a portion of the side surface of the lowermost connection via of each of the first connection via CV1 and the second connection via CV2 may be covered by the channel layer 132.

As discussed above, a two-dimensional electron gas may occur in the upper portion of the channel layer 132 adjacent to the barrier layer 136. The first connection via CV1 and the second connection via CV2 may be connected to the two-dimensional electron gas occurring inside the channel layer 132. For example, the side surface of the lowermost connection via of each of the first connection via CV1 and the second connection via CV2 may be connected to the two-dimensional electron gas. The lower surface of the lowermost connection via of each of the first connection via CV1 and the second connection via CV2 may be positioned at a level lower than the two-dimensional electron gas.

In some implementations, the resistor R may consist of or include a two-dimensional electron gas G1 occurring inside the channel layer 132 located between the first connection via CV1 and the second connection via CV2. The resistor R may be connected between the first connection via CV1 and the second connection via CV2. By being connected between the first connection via CV1 and the second connection via CV2, the resistor R may be connected between the gate pad 212 and the gate runner 214.

In some implementations, the resistance of the resistor R may be determined according to the distance between the first connection via CV1 and the second connection via CV2. For example, as the distance between the first connection via CV1 and the second connection via CV2 increases, the resistance of the resistor R may increase. The distance between the first connection via CV1 and the second connection via CV2 may refer to the length in the second direction Y.

In some implementations, the resistance of the resistor R may be determined according to the width of the channel layer 132 located between the first connection via CV1 and the second connection via CV2. For example, as the width of the channel layer 132 located between the first connection via CV1 and the second connection via CV2 increases, the resistance of the resistor R may decrease. The width of the channel layer 132 between the first connection via CV1 and the second connection via CV2 may refer to the length in the first direction X.

In some implementations, the isolation structure 138 may be positioned on opposite sides of the two-dimensional electron gas G1. The isolation structure 138 may be located between the two-dimensional electron gas G1 and the high electron mobility transistor 100. The isolation structure 138 may be positioned between the two-dimensional electron gas G1 and other devices located in the peripheral region of the high electron mobility transistor 100. The two-dimensional electron gas G1 may be spaced apart and insulated from the high electron mobility transistor 100 and other devices located in the peripheral area of the high electron mobility transistor 100 by the isolation structure 138.

In some implementations, the isolation structures 138 located on opposite sides of the two-dimensional electron gas G1 may be separate from each other, but are not limited to this. For example, the isolation structures 138 may be positioned to surround the two-dimensional electron gas G1.

In some implementations, the isolation structure 138 may extend from the upper surface of the barrier layer 136 toward the lower surface of the channel layer 132. The isolation structure 138 may be located in the barrier layer 136 and the channel layer 132. The isolation structure 138 may penetrate the barrier layer 136 in the third direction Z. The isolation structure 138 may be located on the upper portion of the channel layer 132 adjacent to the barrier layer 136. The upper surface of the isolation structure 138 may be covered by the first protective layer 140.

For example, the isolation structure 138 may be an ion implantation region. In this case, the isolation structure 138 may be part of the barrier layer 136 and the channel layer 132. The ions may include, for example, Ar ions or N ions, but are not limited to these.

As another example, the isolation structure 138 may be an insulating pattern. In this case, the isolation structure 138 may be formed by etching portions of the barrier layer 136 and the channel layer 132 to form a trench, which is then filled with an insulating material. The insulating material may include, for example, silicon oxide (SiO₂) or silicon nitride (Si₃N₄), but is not limited thereto.

In some implementations, the semiconductor device may apply a uniform voltage to the gate electrode 155 by including a resistor R connected between the gate pad 212 and the gate runner 214. In some implementations, by connecting the first connection via CV1 connected to the gate pad 212 and the second connection via CV2 connected to the gate runner 214 to the channel layer 132, the resistor R may be formed using the two-dimensional electron gas occurring inside the channel layer 132. When a separate resistor is provided outside the semiconductor device and connected to it, the size of the package including the semiconductor device and the separate resistor may increase, and the reliability of the gate operation may decrease. However, as described herein, a resistor R may be added to the electrical connection path between the gate pad 212 and the gate electrode 155 without increasing the size of the semiconductor device and the package containing it, and the reliability of the gate operation may be ensured as the resistor R is provided in the semiconductor device.

In the manufacturing process of a semiconductor device, by adjusting the distance between the first connection via CV1 and the second connection via CV2, and/or the cross-sectional area of the channel layer 132 between the first connection via CV1 and the second connection via CV2, a resistor R with various resistances may be formed to adjust the resistance of the gate electrode 155 of the high electron mobility transistor 100.

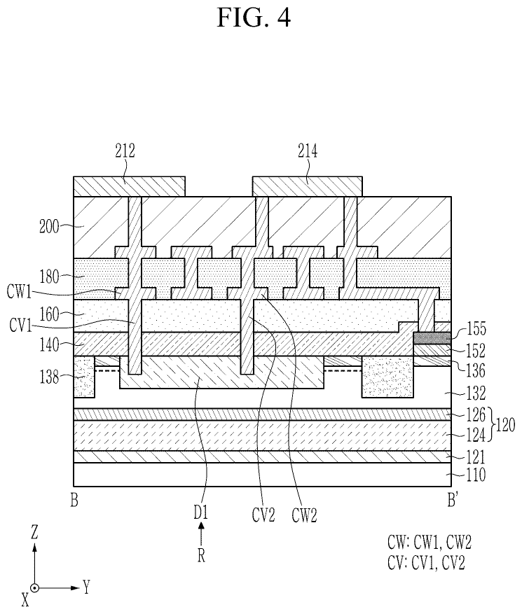

Below, variations of the example shown in FIGS. 1 to 3 will be described with reference to FIGS. 4 to 15. Therefore, redundant descriptions for components corresponding to the examples shown in FIGS. 1 to 3 will be omitted, and the differences will be mainly described.

Below, with reference to FIG. 4, a case will be described in which the resistor of the semiconductor device is composed of a doping region rather than a two-dimensional electron gas.

FIG. 4 is a cross-sectional view of an example of a semiconductor device, taken along line B-B′ of FIG. 1. Hereinafter, descriptions overlapping with previous examples will be brief or omitted, and the focus will be on explaining the differences.

Referring to FIG. 4, a doping region D1 (or doped region) may be located in the channel layer 132 of the semiconductor device. The doping region D1 may extend through the barrier layer 136 into the channel layer 132. The lower surface of the doping region D1 may be positioned at a level lower than the two-dimensional electron gas occurring in the channel layer 132.

In some implementations, the upper surface of the doping region D1 may be positioned at substantially the same level as the upper surface of the barrier layer 136, but the positioning is not limited to this. For example, the upper surface of the doping region D1 may be positioned at a lower level than the upper surface of the barrier layer 136.

In some implementations, the doping region D1 may be an ion implantation region. For example, the doping region D1 may be a region where Si ions are implanted. In this case, the doping type of the doping region D1 may be of the n-type. As another example, the doping region D1 may be a region where Mg ions are implanted. In this case, the doping type of the doping region D1 may be of the p-type. The material of the doping region D1 is not limited to the aforementioned examples and may be varied.

In some implementations, isolation structures 138 may be located on opposite sides of the doping region D1. The doping region D1 may be spaced apart and insulated from the high electron mobility transistor 100 by the isolation structures 138. The doping region D1 may be spaced apart and insulated from other devices located in the peripheral region of the high electron mobility transistor 100 by the isolation structures 138.

In some implementations, the isolation structures 138 located on opposite sides of the doping region D1 may be separated from each other, but this is not limited thereto. For example, the isolation structures 138 may be positioned to surround the doping region D1.

In some implementations, the first connection via CV1 and the second connection via CV2 may be connected to the doping region D1. The lower surfaces of the first connection via CV1 and the second connection via CV2 may be positioned at a level lower than the upper surface of the doping region D1 and may be positioned at a level higher than the lower surface of the doping region D1, but are not limited to this. In some cases, the lower surfaces of the first connection via CV1 and the second connection via CV2 may be positioned at the same level as the upper surface of the doping region D1. The lower surface of the lowermost connection via of each of the first connection via CV1 and the second connection via CV2 may be covered by the doping region D1.

In some implementations, the doping region D1 may be located between the first connection via CV1 and the second connection via CV2. In some cases, the doping region D1 may be located further outside the region between the first connection via CV1 and the second connection via CV2, but it is not limited to this. Portions of the side surfaces of the lowermost connection vias of each of the first connection via CV1 and the second connection via CV2 may be covered by the doping region D1.

In some implementations, the resistor R may be composed of a doping region D1 located between the first connection via CV1 and the second connection via CV2. The resistor R may be connected between the first connection via CV1 and the second connection via CV2. By being connected between the first connection via CV1 and the second connection via CV2, the resistor R may be connected between the gate pad 212 and the gate runner 214.

In some implementations, the resistance of the resistor R may be determined based on the distance between the first connection via CV1 and the second connection via CV2. For example, as the distance between the first connection via CV1 and the second connection via CV2 increases, the resistance of the resistor R may increase. The distance between the first connection via CV1 and the second connection via CV2 may refer to the length in the second direction Y.

In some implementations, the resistance of the resistor R may be determined based on the cross-sectional area of the doping region D1 between the first connection via CV1 and the second connection via CV2. For example, as the cross-sectional area of the doping region D1 between the first connection via CV1 and the second connection via CV2 increases, the resistance of the resistor R may decrease. The cross-sectional area of the doping region D1 between the first connection via CV1 and the second connection via CV2 may refer to the area in a cross-sectional plane defined by the first direction X and the third direction Z.

The semiconductor device may apply a uniform voltage to the gate electrode 155 by including a resistor R connected between the gate pad 212 and the gate runner 214. By connecting a first connection via CV1 connected to the gate pad 212 and a second connection via CV2 connected to the gate runner 214 to a doping region D1 located in the channel layer 132, a resistor R may be formed using the doping region D1 located in the channel layer 132. For example, when a separate resistor is provided outside the semiconductor device and connected to the semiconductor device, the size of the package including the semiconductor device and the separate resistor increases, and power loss may occur. As described herein, a resistor R may be added to the electrical connection path between the gate pad 212 and the gate electrode 155 without increasing the size of the semiconductor device and the package containing it, and power loss may also be reduced as the resistor R is provided in the semiconductor device.

In the manufacturing process of a semiconductor device, a resistor R with various resistances may be formed by adjusting the distance between the first connection via CV1 and the second connection via CV2, and/or the cross-sectional area of the doping region D1 between the first connection via CV1 and the second connection via CV2, thereby controlling the resistance of the gate electrode 155 of the high electron mobility transistor 100.

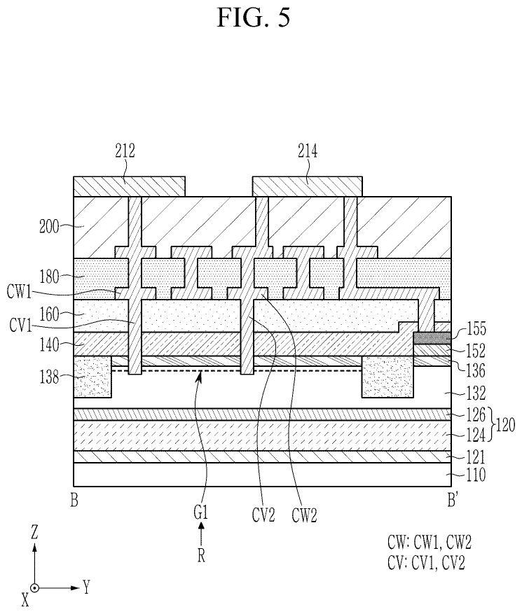

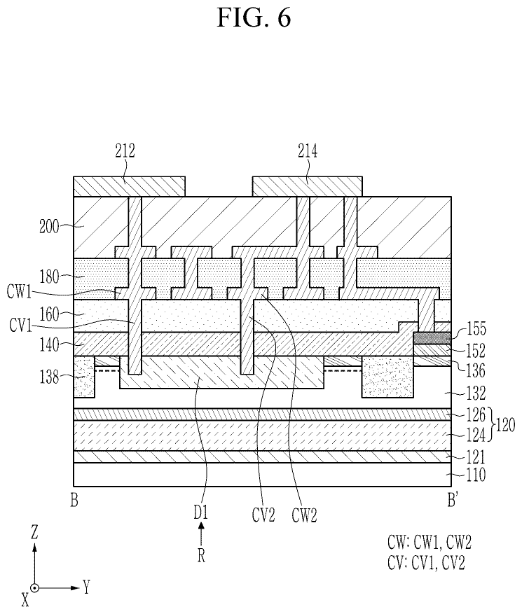

Below, with reference to FIGS. 5 and 6, a case will be described in which the resistance of a resistor is adjusted by varying the length of the connection wiring and/or the number of connection vias of a semiconductor device.

FIGS. 5 and 6 are cross-sectional views of an example of a semiconductor device, taken along line B-B′ of FIG. 1. In the following, explanations that overlap with the examples shown in FIGS. 3 and 4 will be briefly addressed or omitted, focusing primarily on the differences.

In the examples shown in FIGS. 5 and 6, the length of the second connection wiring CW2 that constitutes the shortest path between the gate runner 214 and the resistor R may differ from the examples shown in FIGS. 3 and 4. For example, the length of the second connection wiring CW2 located on the third protective layer 180 among the second connection wiring CW2 connecting the gate runner 214 and the resistor R by the shortest path may be longer in the examples shown in FIGS. 5 and 6 than in the examples shown in FIGS. 3 and 4. Accordingly, the resistance of the resistor R in FIGS. 5 and 6 may be greater than the resistance of the resistor R in FIGS. 3 and 4.

In the aforementioned example, the case where the length of the second connecting wire CW2 is different was illustrated, but it is not limited to this, and the resistance of the resistor R may also be adjusted otherwise, e.g., by varying the cross-sectional area of the second connecting wire CW2.

In the aforementioned example, although the case where the length of the second connection wiring CW2 connecting the resistor R and the gate runner 214 in the shortest path is different is shown, adjustment of the resistance is not limited to this. The resistance of the resistor R may also be adjusted, for example, by varying the length of the first connection wiring CW1 connecting the resistor R and the gate pad 212 in the shortest path.

In addition, it is possible to adjust the resistance of the resistor R by varying the number of first connection vias CV1 that connect the gate pad 212 and the resistor R along the shortest path, and the number of second connection vias CV2 that connect the gate runner 214 and the resistor R along the shortest path. For example, the greater the number of first connection vias CV1 connecting the gate pad 212 and the resistor R along the shortest path, and the number of second connection vias CV2 connecting the gate runner 214 and the resistor R along the shortest path, the greater the resistance of the resistor R may be.

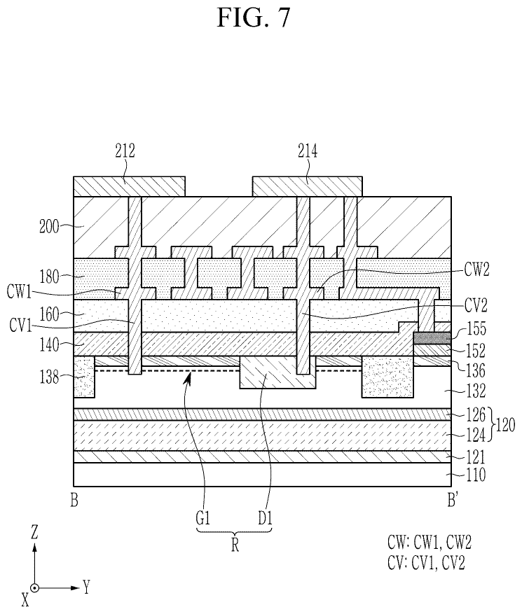

Below, with reference to FIG. 7, an example will be described in which the resistor of a semiconductor device is composed of a two-dimensional electron gas and a doping region.

FIG. 7 is a cross-sectional view of an example of a semiconductor device taken along the line B-B′ of FIG. 1. In the following, descriptions overlapping with previous examples will be brief or omitted, focusing mainly on the differences.

Referring to FIG. 7, a two-dimensional electron gas may occur inside the channel layer 132 of the semiconductor device. In addition, a doping region D1 may be located in the channel layer 132 of the semiconductor device.

In some implementations, either the first connection via CV1 or the second connection via CV2 may be connected to the channel layer 132, and the other of the first connection via CV1 and the second connection via CV2 may be connected to the doping region D1. For example, as shown in FIG. 7, the first connection via CV1 may be connected to the channel layer 132 and the second connection via CV2 may be connected to the doping region D1, but this is not limited thereto. As another example, the first connection via CV1 may be connected to the doping region D1, and the second connection via CV2 may be connected to the channel layer 132.

In some implementations, the resistor R may consist of a two-dimensional electron gas G1 occurring inside the channel layer 132 located between the first connection via CV1 and the second connection via CV2, and a doping region D1 located between the first connection via CV1 and the second connection via CV2.

For example, the resistivity of the two-dimensional electron gas G1 and the doping region D1 may differ. In some implementations, the resistance of the resistor R may be determined according to the ratio of the two-dimensional electron gas G1 to the doping region D1 that consists of the resistor R. For example, the ratio of the two-dimensional electron gas G1 to the doping region D1 may refer to the length ratio in the second direction Y between the first connection via CV1 and the second connection via CV2. For example, when the length of the component with relatively high resistivity among the two-dimensional electron gas G1 and the doping region D1 is increased, the resistance of the resistor R may increase, and when the length of the component with relatively low resistivity is increased, the resistance of the resistor R may decrease.

In the aforementioned example, the two-dimensional electron gas G1 and the doping region D1 may be adjacent in the second direction Y between the first connection via CV1 and the second connection via CV2, which are spaced apart in the second direction Y. It is depicted that one of the first connection via CV1 and the second connection via CV2 is connected to the two-dimensional electron gas G1, and the other is connected to the doping region D1. For example, the resistor composed of the two-dimensional electron gas G1 and the resistor composed of the doping region D1 are connected in series between the gate pad 212 and the gate runner 214. However, configurations are not limited thereto. For example, the two-dimensional electron gas G1 and the doping region D1 may be adjacent in the first direction X and extend in the same length along the second direction Y. In this case, the first connection via CV1 may be connected to one side in the second direction Y of the two-dimensional electron gas G1 and the doping region D1, and the second connection via CV2 may be connected to the other side in the second direction Y of the two-dimensional electron gas G1 and the doping region D1. For example, the resistor composed of the two-dimensional electron gas G1 and the resistor composed of the doping region D1 may also be connected in parallel between the gate pad 212 and the gate runner 214.

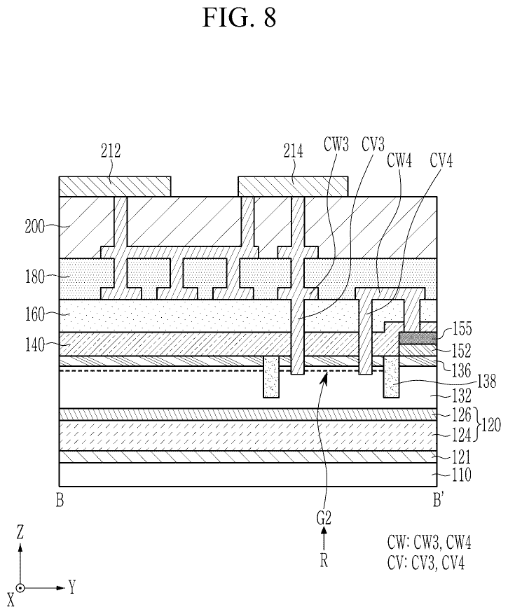

Below, with reference to FIGS. 8 to 12, a description will be given of a case in which a resistor of a semiconductor device is connected between a gate runner and a gate electrode of a high electron mobility transistor.

FIGS. 8, 9, 10, 11, and 12 are cross-sectional views of an example of a semiconductor device taken along line B-B′ of FIG. 1. The examples shown in FIGS. 8, 9, 10, 11, and 12 may correspond to the examples shown in FIGS. 3, 4, 5, 6, and 7, respectively.

Referring to FIG. 8, the resistor R of the semiconductor device may be connected between the gate runner 214 and the gate electrode 155 of the high electron mobility transistor 100. The connection wiring CW and connection via CV may include a third connection wiring CW3 and a third connection via CV3 that connect the gate runner 214 and the resistor R. The connection wiring CW and connection via CV may include a fourth connection wiring CW4 and a fourth connection via CV4 that connect the gate electrode 155 and the resistor R.

In some implementations, the third connection via CV3 and the fourth connection via CV4 may be connected to the channel layer 132. The third connection via CV3 and the fourth connection via CV4 may be connected to the channel layer 132 by penetrating the barrier layer 136. A two-dimensional electron gas may occur at the upper portion of the channel layer 132 adjacent to the barrier layer 136. The third connection via CV3 and the fourth connection via CV4 may be connected to the two-dimensional electron gas occurring inside the channel layer 132. For example, the side surfaces of the third connection via CV3 and the fourth connection via CV4 may be connected to the two-dimensional electron gas. The lower surfaces of the third connection via CV3 and the fourth connection via CV4 may be positioned at a level lower than the two-dimensional electron gas.

In some implementations, the resistor R may be composed of a two-dimensional electron gas G2 that occurs in the channel layer 132 located between the third connection via CV3 and the fourth connection via CV4. The resistor R may be connected between the third connection via CV3 and the fourth connection via CV4. By being connected between the third connection via CV3 and the fourth connection via CV4, the resistor R may be connected between the gate runner 214 and the gate electrode 155.

In some implementations, the resistance of the resistor R may be determined based on the distance between the third connection via CV3 and the fourth connection via CV4. For example, as the distance between the third connection via CV3 and the fourth connection via CV4 increases, the resistance of the resistor R may also increase. The distance between the third connection via CV3 and the fourth connection via CV4 may refer to the length in the second direction Y.

In some implementations, the resistance of the resistor R may be determined according to the width of the channel layer 132 between the third connection via CV3 and the fourth connection via CV4. For example, as the width of the channel layer 132 positioned between the third connection via CV3 and the fourth connection via CV4 increases, the resistance of the resistor R may decrease. The width of the channel layer 132 between the third connection via CV3 and the fourth connection via CV4 may refer to the length in the first direction X.

The semiconductor device may apply a uniform voltage to the gate electrode 155 as it includes a resistor R connected between the gate runner 214 and the gate electrode 155. By connecting the third connection via CV3 connected to the gate runner 214 and the fourth connection via CV4 connected to the gate electrode 155 to the channel layer 132, a resistor R may be formed using the two-dimensional electron gas occurring inside the channel layer 132. For example, when a separate resistor is provided outside the semiconductor device and connected to it, the size of the package containing the semiconductor device and the separate resistor may increase, and the reliability of the gate operation may decrease. As described herein, it is possible to add a resistor R to the electrical connection path between the gate pad 212 and the gate electrode 155 without increasing the size of the semiconductor device and the package containing it, and the reliability of the gate operation may be ensured as the resistor R is provided in the semiconductor device.

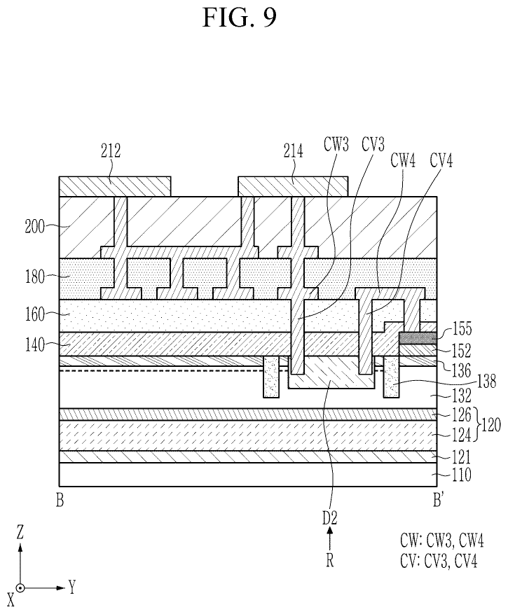

Referring to FIG. 9, a doping region D2 may be located in the channel layer 132 of the semiconductor device. The description of the doping region D1 in FIGS. 1 to 7 may be applied identically or similarly to the description of the doping region D2.

In some implementations, the third connection via CV3 and the fourth connection via CV4 may be connected to the doping region D2. The lower surfaces of the third connection via CV3 and the fourth connection via CV4 may be positioned at a level lower than the upper surface of the doping region D2 and may be positioned at a level higher than the lower surface of the doping region D2, but are not limited to this. In some implementations, the lower surfaces of the third connection via CV3 and the fourth connection via CV4 may be positioned at the same level as the upper surface of the doping region D1. The lower surface of each of the lowermost connection vias of the third connection via CV3 and the fourth connection via CV4 may be covered by the doping region D2.

In some implementations, the doping region D2 may be located between the third connection via CV3 and the fourth connection via CV4. In some cases, the doping region D2 may be positioned further outward the region between the third connection via CV3 and the fourth connection via CV4, but the arrangement is not limited to this. Portions of the side surfaces of each of the lowermost connection vias of the third connection via CV3 and the fourth connection via CV4 may be covered by the doping region D2.

In some implementations, the resistor R may be composed of the doping region D2 located between the third connection via CV3 and the fourth connection via CV4. The resistor R may be connected between the third connection via CV3 and the fourth connection via CV4. By being connected between the third connection via CV3 and the fourth connection via CV4, the resistor R may be connected between the gate runner 214 and the gate electrode 155.

In some implementations, the resistance of the resistor R may be determined based on the distance between the third connection via CV3 and the fourth connection via CV4. For example, as the distance between the third connection via CV3 and the fourth connection via CV4 increases, the resistance of the resistor R may increase. The distance between the third connection via CV3 and the fourth connection via CV4 may refer to the length in the second direction Y.

In some implementations, the resistance of the resistor R may be determined according to the cross-sectional area of the doping region D2 between the third connection via CV3 and the fourth connection via CV4. For example, as the cross-sectional area of the doping region D2 between the third connection via CV3 and the fourth connection via CV4 increases, the resistance of the resistor R may decrease. The cross-sectional area of the doping region D2 between the third connection via CV3 and the fourth connection via CV4 may refer to the cross-sectional area in a plane defined by the first direction X and the third direction Z.

The semiconductor device may apply a uniform voltage to the gate electrode 155 by including a resistor R connected between the gate runner 214 and the gate electrode 155. By connecting the third connection via CV3 connected to the gate runner 214 and the fourth connection via CV4 connected to the gate electrode 155 to the doping region D2 located in the channel layer 132, the resistor R may be formed using the doping region D2 located in the channel layer 132. For example, when a separate resistor is provided outside the semiconductor device and connected to it, the size of the package including the semiconductor device and the separate resistor increases, and power loss may occur. As described herein, a resistor R may be added to the electrical connection path between the gate pad 212 and the gate electrode 155 without increasing the size of the semiconductor device and the package containing it, and power loss may also be reduced as the resistor R is provided in the semiconductor device.

In the manufacturing process of a semiconductor device, by adjusting the distance between the third connection via CV3 and the fourth connection via CV4, and/or the cross-sectional area of the doping region D2 between the third connection via CV3 and the fourth connection via CV4, a resistor R with various resistances may be formed to adjust the resistance of the gate electrode 155 of the high electron mobility transistor 100.

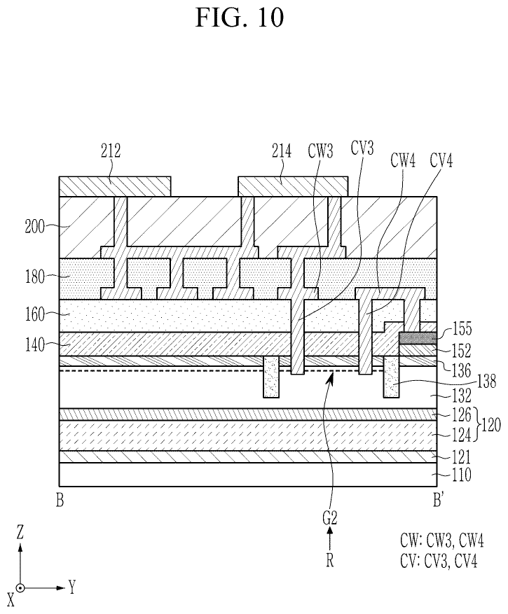

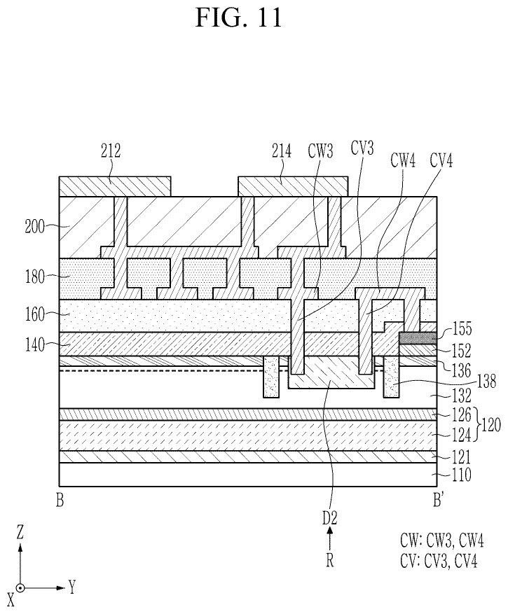

In the examples shown in FIGS. 10 and 11, the length of the third connection wiring CW3 that constitutes the shortest path between the gate runner 214 and the resistor R may differ from the examples shown in FIGS. 3 and 4 and those shown in FIGS. 8 and 9. For example, the length of the third connection wiring CW3 located on the third protective layer 180 among the third connection wiring CW3 connecting the gate runner 214 and the resistor R via the shortest path may be longer in the examples shown in FIGS. 10 and 11 than in the examples shown in FIGS. 8 and 9. Accordingly, the resistance of the resistor R in FIGS. 10 and 11 may be greater than the resistance of the resistor R in FIGS. 8 and 9.

In the aforementioned example, the case where the length of the third connection wire CW3 is different is illustrated, but adjustment of the resistance is not limited to this, and the resistance of the resistor R may also be adjusted by, for example, varying the cross-sectional area of the third connection wire CW3.

Additionally, in the aforementioned example, although the case where the length of the third connection wiring CW3 connecting the resistor R and the gate runner 214 by the shortest path is different is illustrated, adjustment of the resistance is not limited to this. The resistance of the resistor R may also be adjusted by, for example, varying the length of the fourth connection wiring CW4 that connects the resistor R and the gate electrode 155 by the shortest path.

Additionally, the resistance of the resistor R may be adjusted by varying the number of third connection vias CV3 that connect the gate runner 214 and the resistor R via the shortest path, and the number of fourth connection vias CV4 that connect the gate electrode 155 and the resistor R via the shortest path. For example, the greater the number of third connection vias CV3 connecting the gate runner 214 and the resistor R via the shortest path, and the greater the number of fourth connection vias CV4 connecting the gate electrode 155 and the resistor R via the shortest path, the greater the resistance of the resistor R may be.

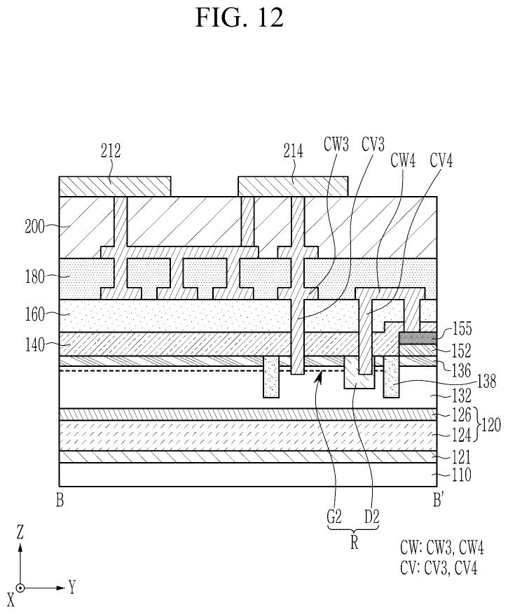

Referring to FIG. 12, a two-dimensional electron gas may occur inside the channel layer 132 of the semiconductor device. A doping region D2 may be located in the channel layer 132 of the semiconductor device.

In some implementations, either the third connection via CV3 or the fourth connection via CV4 is connected to the channel layer 132, and the other of the third connection via CV3 and the fourth connection via CV4 may be connected to the doping region D2. For example, as shown in FIG. 12, the third connection via CV3 may be connected to the channel layer 132 and the fourth connection via CV4 may be connected to the doping region D2, but the arrangement is not limited to this. As another example, the third connection via CV3 may be connected to the doping region D2, and the fourth connection via CV4 may be connected to the channel layer 132.

In some implementations, the resistor R may consist of or include the two-dimensional electron gas G2 occurring inside the channel layer 132 located between the third connection via CV3 and the fourth connection via CV4, and the doping region D2 located between the third connection via CV3 and the fourth connection via CV4.

For example, the resistivity of the two-dimensional electron gas G2 and the doping region D2 may differ. In some implementations, the resistance of the resistor R may be determined according to the ratio of the two-dimensional electron gas G2 to the doping region D2 constituting the resistor R. For example, the ratio of the two-dimensional electron gas G2 to the doping region D2 may refer to the length ratio in the second direction Y between the third connection via CV3 and the fourth connection via CV4. For example, when the length of the component with relatively high resistivity among the two-dimensional electron gas G2 and the doping region D2 is increased, the resistance of the resistor R may increase, and when the length of the component with relatively low resistivity is increased, the resistance of the resistor R may decrease.

In the aforementioned example, the two-dimensional electron gas G2 and the doping region D2 may be adjacent in the second direction Y between the third connection via CV3 and the fourth connection via CV4, which are spaced apart in the second direction Y. One of the third connection via CV3 and the fourth connection via CV4 is shown to be connected to the two-dimensional electron gas G2, and the other is connected to the doping region D2. That is, the resistor composed of the two-dimensional electron gas G2 and the resistor composed of the doping region D2 are connected in series between the gate runner 214 and the gate electrode 155. However, the resistor configuration is not limited to this. For example, the two-dimensional electron gas G2 and the doping region D2 may be adjacent in the first direction X and may extend to the same length along the second direction Y. In this case, the third connection via CV3 may be connected to one side in the second direction Y of the two-dimensional electron gas G2 and the doping region D2, and the fourth connection via CV4 may be connected to the other side in the second direction Y of the two-dimensional electron gas G2 and the doping region D2. For example, the resistor composed of the two-dimensional electron gas G2 and the resistor composed of the doping region D2 may also be connected in parallel between the gate runner 214 and the gate electrode 155.

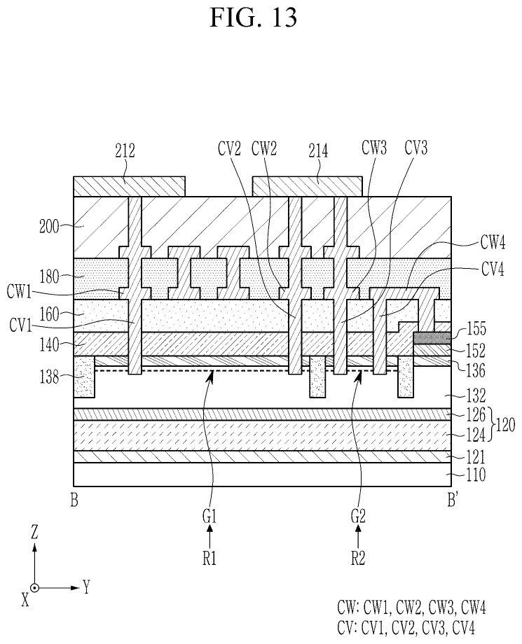

Below, with reference to FIGS. 13 to 15, a description will be given of an example in which the semiconductor device includes a first resistor connected between the gate pad and the gate runner, and a second resistor connected between the gate runner and the gate electrode of the high electron mobility transistor.

FIGS. 13, 14, and 15 are cross-sectional views of a semiconductor device, taken along line B-B′ of FIG. 1.

The semiconductor device may include a first resistor R1 connected between the gate pad 212 and the gate runner 214, and a second resistor R2 connected between the gate runner 214 and the gate electrode 155. The connection wiring CW and connection via CV may include a first connection wiring CW1 and a first connection via CV1 connecting between the gate pad 212 and the first resistor R1. The connection wiring CW and connection via CV may include a second connection wiring CW2 and a second connection via CV2 connecting between the gate runner 214 and the first resistor R1. The connection wiring CW and connection via CV may include a third connection wiring CW3 and a third connection via CV3 connecting between the gate runner 214 and the second resistor R2. The connection wiring CW and connection via CV may include a fourth connection wiring CW4 and a fourth connection via CV4 connecting between the gate electrode 155 and the second resistor R2.

Referring to FIG. 13, the first connection via CV1, second connection via CV2, third connection via CV3, and fourth connection via CV4 of the semiconductor device may be connected to the channel layer 132. The first connection via CV1, second connection via CV2, third connection via CV3, and fourth connection via CV4 may be connected to the two-dimensional electron gas occurring inside the channel layer 132.

In some implementations, an isolation structure 138 may be further positioned between the second connection via CV2 and the third connection via CV3. The isolation structure 138 may extend through the barrier layer 136 to a level lower than where the two-dimensional electron gas occurs in the channel layer 132. The two-dimensional electron gas in the channel layer 132 may be separated by the isolation structure 138.

In some implementations, the first resistor R1 may be composed of a two-dimensional electron gas G1 occurring inside the channel layer 132 located between the first connection via CV1 and the second connection via CV2. The first resistor R1 may be connected between the first connection via CV1 and the second connection via CV2. By being connected between the first connection via CV1 and the second connection via CV2, the first resistor R1 may be connected between the gate pad 212 and the gate runner 214.

In some implementations, the second resistor R2 may be composed of a two-dimensional electron gas G2 that occurs inside the channel layer 132 located between the third connection via CV3 and the fourth connection via CV4. The second resistor R2 may be connected between the third connection via CV3 and the fourth connection via CV4. By being connected between the third connection via CV3 and the fourth connection via CV4, the second resistor R2 may be connected between the gate runner 214 and the gate electrode 155.

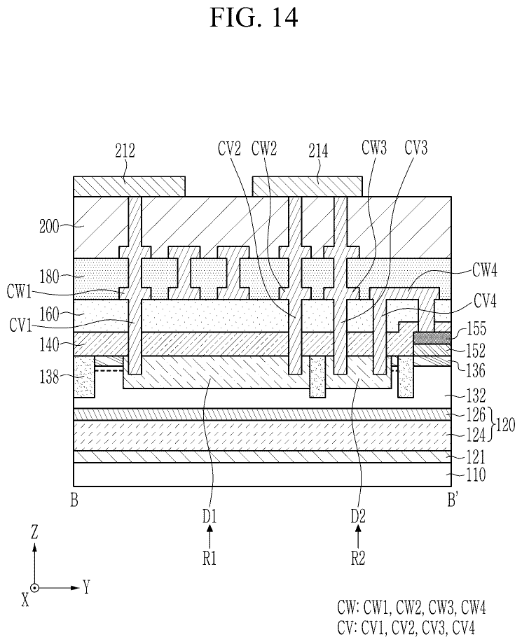

Referring to FIG. 14, in the semiconductor device, the first connection via CV1 and the second connection via CV2 may be connected to the first doping region D1, and the third connection via CV3 and the fourth connection via CV4 may be connected to the second doping region D2.

In some implementations, an isolation structure 138 may be further positioned between the second connection via CV2 and the third connection via CV3. The first doping region D1 and the second doping region D2 may be spaced apart and insulated by the isolation structure 138. The isolation structure 138 may be located between the first doping region D1 and the second doping region D2. In some implementations, the lower surface of the isolation structure 138 may be at the same level as or lower than the lower surfaces of the first doping region D1 and the second doping region D2. For example, after the first doping region D1 and the second doping region D2 are integrally formed, they may be separated into the first doping region D1 and the second doping region D2 as the isolation structure 138 is formed, but this is not limited thereto. In some cases, the first doping region D1 and the second doping region D2 may be formed separately, and the isolation structure 138 may be formed between the first doping region D1 and the second doping region D2.

In some implementations, the first resistor R1 may be composed of a first doping region D1 located between the first connection via CV1 and the second connection via CV2. The first resistor R1 may be connected between the first connection via CV1 and the second connection via CV2. By being connected between the first connection via CV1 and the second connection via CV2, the first resistor R1 may be connected between the gate pad 212 and the gate runner 214.

In some implementations, the second resistor R2 may be composed of a second doping region D2 located between the third connection via CV3 and the fourth connection via CV4. The second resistor R2 may be connected between the third connection via CV3 and the fourth connection via CV4. By being connected between the third connection via CV3 and the fourth connection via CV4, the second resistor R2 may be connected between the gate runner 214 and the gate electrode 155.

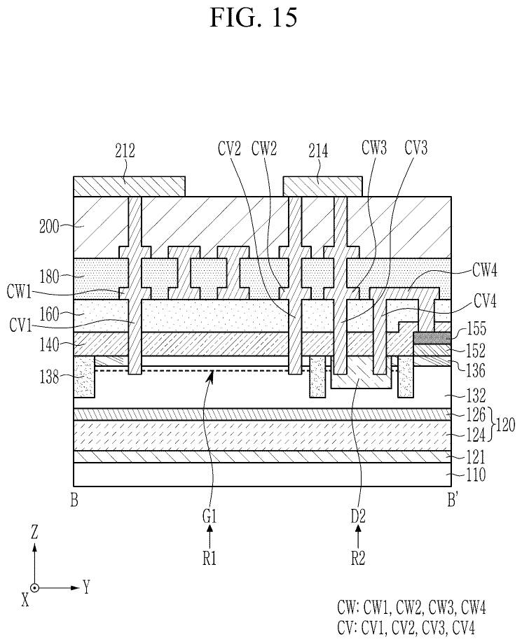

Referring to FIG. 15, the first connection via CV1 and the second connection via CV2 of the semiconductor device may be connected to the channel layer 132. The first connection via CV1 and the second connection via CV2 may be connected to the two-dimensional electron gas G1 occurring inside the channel layer 132. In some implementations, the third connection via CV3 and the fourth connection via CV4 may be connected to the second doping region D2.

In some implementations, an isolation structure 138 may further be positioned between the second connection via CV2 and the third connection via CV3. By the isolation structure 138, the two-dimensional electron gas G1 and the second doping region D2 may be spaced apart and insulated.

In some implementations, the first resistor R1 may be composed of a two-dimensional electron gas G1 occurring inside the channel layer 132 located between the first connection via CV1 and the second connection via CV2. The first resistor R1 may be connected between the first connection via CV1 and the second connection via CV2. By being connected between the first connection via CV1 and the second connection via CV2, the first resistor R1 may be connected between the gate pad 212 and the gate runner 214.

In some implementations, the second resistor R2 may be formed of a second doping region D2 located between the third connection via CV3 and the fourth connection via CV4. The second resistor R2 may be connected between the third connection via CV3 and the fourth connection via CV4. By being connected between the third connection via CV3 and the fourth connection via CV4, the second resistor R2 may be connected between the gate runner 214 and the gate electrode 155.

In the aforementioned example, the first resistor R1 is depicted as being composed of a two-dimensional electron gas and the second resistor R2 as being composed of a doping region, but the resistor configuration is not limited to this. For example, the first resistor R1 could be composed of a doping region, and the second resistor R2 could be composed of a two-dimensional electron gas. For example, the first resistor R1 may be composed of a first doping region D1 located between the first connection via CV1 and the second connection via CV2, and the second resistor R2 may be composed of a two-dimensional electron gas G2 occurring in the channel layer 132 located between the third connection via CV3 and the fourth connection via CV4. The first connection via CV1 and the second connection via CV2 may be connected to the first doping region D1, and the third connection via CV3 and the fourth connection via CV4 may be connected to the channel layer 132. The third connection via CV3 and the fourth connection via CV4 may be connected to the two-dimensional electron gas G2 located in the channel layer 132. An isolation structure 138 may be located between the second connection via CV2 and the third connection via CV3. By the isolation structure 138, the first doping region D1 and the two-dimensional electron gas G2 may be spaced apart and insulated from one another.

In the examples shown in FIGS. 13, 14, and 15, the resistance of the first resistor R1 may be determined according to the distance between the first connection via CV1 and the second connection via CV2, and the resistance of the second resistor R2 may be determined according to the distance between the third connection via CV3 and the fourth connection via CV4. In the case of the first resistor R1, as it is connected between the gate pad 212 and the gate runner 214, it may be connected to the gate electrode 155 of a plurality of high electron mobility transistors 100 connected to the gate runner 214. In the case of the second resistor R2, as it is connected between the gate runner 214 and the gate electrode 155, it may be connected to the gate electrode 155 of any one of the plurality of high electron mobility transistors 100 connected to the gate runner 214. In some implementations, in the manufacturing process of the semiconductor device, when it is desired to adjust the overall gate resistance for the plurality of high electron mobility transistors 100, the length between the first connection via CV1 and the second connection via CV2 may be adjusted, and when it is desired to adjust the gate resistance for each high electron mobility transistor 100 individually, the distance between the third connection via CV3 and the fourth connection via CV4 may be adjusted.

The description provided for FIGS. 5 and 6 may be applied to the examples shown in FIGS. 13, 14, and 15. According to this, by adjusting the length of at least some of the connecting wiring CW that connects at least one of the gate pad 212, gate runner 214, and gate electrode 155 to each of the first resistor R1 and second resistor R2 via the shortest path, the resistance of each of the first resistor R1 and second resistor R2 may be adjusted. Additionally, by adjusting the number of connecting vias CV that connect at least one of the gate pad 212, gate runner 214, and gate electrode 155 to each of the first resistor R1 and second resistor R2 via the shortest path, the resistance of each of the first resistor R1 and second resistor R2 may also be adjusted.

The example shown in FIG. 7 may be merged with the examples shown in FIGS. 13, 14, and 15. According to this, one or each of the first resistor R1 and the second resistor R2 may be composed of a two-dimensional electron gas and a doping region. For example, the two-dimensional electron gas and doping region included in each of the first resistor R1 and the second resistor R2 may be connected in series or in parallel.

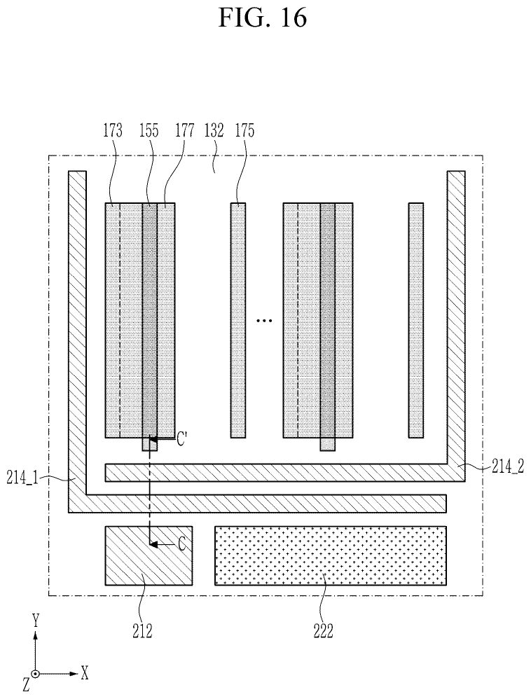

The following describes an example in which the resistor of a semiconductor device is connected between the gate pad and the first gate runner, and between the first gate runner and the second gate runner, with reference to FIGS. 16 to 19. The examples shown in FIGS. 16 to 19 are variations of the examples shown in FIGS. 13 to 15. In the examples shown in FIGS. 16 to 19, the first resistor R11 and the second resistor R12 may correspond to the first resistor R1 and the second resistor R2 in the examples shown in FIGS. 13 to 15, respectively. Furthermore, the examples shown in FIGS. 16 to 19 are variations of the example shown in FIGS. 1 to 3. Therefore, because the description of components corresponding to the examples shown in FIGS. 13 to 15, and the same components as the example shown in FIGS. 1 to 3 may be applied in the same or similar manner, redundant descriptions are omitted and the differences are mainly described.

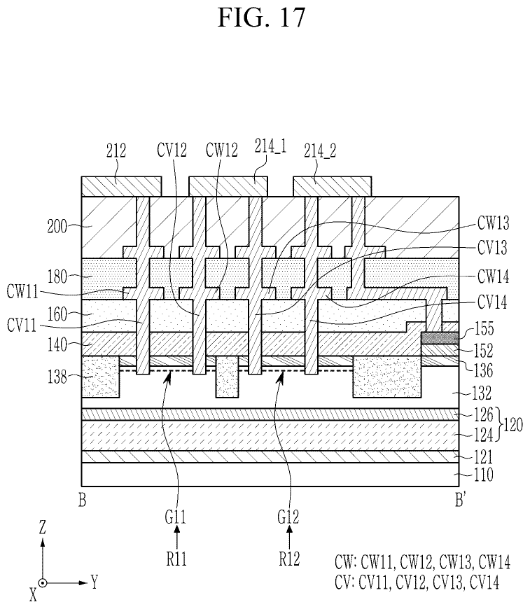

FIG. 16 is a plan view of an example of a semiconductor device. FIGS. 17, 18, and 19 are cross-sectional views of examples of semiconductor devices taken along line C-C′ of FIG. 16. For convenience and clarity of illustration, FIG. 16 only shows the source electrode 173 and field dispersion layer 177, drain electrode 175, gate electrode 155, gate pad 212, gate runner 214, and source pad 222 located on the channel layer 132, and other components are omitted.

Referring to FIGS. 16 to 19, the semiconductor device may include a first gate runner 214_1 and a second gate runner 214_2 extending along the edge of the high electron mobility transistor 100. In FIG. 16, the first gate runner 214_1 and the second gate runner 214_2 are shown as being separate, but this is not limiting. For example, the first gate runner 214_1 and the second gate runner 214_2 may be connected to each other in different regions. The shape of the first gate runner 214_1 and the second gate runner 214_2 in a plan view is not limited to the example shown in FIG. 16 and may be variously modified.

The semiconductor device may include a first resistor R11 connected between a gate pad 212 and a first gate runner 214_1, and a second resistor R12 connected between the first gate runner 214_1 and a second gate runner 214_2. The connection wiring CW and connection via CV may include a first connection wiring CW11 and a first connection via CV11 connecting the gate pad 212 and the first resistor R11. The connection wiring CW and connection via CV may include a second connection wiring CW12 and a second connection via CV12 connecting the first gate runner 214_1 and the first resistor R11. The connection wiring CW and connection via CV may include a third connection wiring CW13 and a third connection via CV13 connecting the first gate runner 214_1 and the second resistor R12. The connection wiring CW and connection via CV may include a fourth connection wiring CW14 and a fourth connection via CV14 connecting the second gate runner 214_2 and the second resistor R12.

Referring to FIG. 17, the first connection via CV11, second connection via CV12, third connection via CV13, and fourth connection via CV14 of the semiconductor device may be connected to the channel layer 132. The first connection via CV11, second connection via CV12, third connection via CV13, and fourth connection via CV14 may be connected to the two-dimensional electron gas occurring inside the channel layer 132.

In some implementations, an isolation structure 138 may be further positioned between the second connection via CV12 and the third connection via CV13. The isolation structure 138 may extend through the barrier layer 136 to a level lower than where the two-dimensional electron gas occurs in the channel layer 132. The two-dimensional electron gas in the channel layer 132 may be separated by the isolation structure 138.

In some implementations, the first resistor R11 may be composed of a two-dimensional electron gas G11 occurring inside the channel layer 132 located between the first connection via CV11 and the second connection via CV12. The first resistor R11 may be connected between the first connection via CV11 and the second connection via CV12. By being connected between the first connection via CV11 and the second connection via CV12, the first resistor R11 may be connected between the gate pad 212 and the first gate runner 214_1.

In some implementations, the second resistor R12 may consist of a two-dimensional electron gas G12 occurring in the channel layer 132 located between the third connection via CV13 and the fourth connection via CV14. The second resistor R12 may be connected between the third connection via CV13 and the fourth connection via CV14. By being connected between the third connection via CV13 and the fourth connection via CV14, the second resistor R12 may be connected between the first gate runner 214_1 and the second gate runner 214_2.

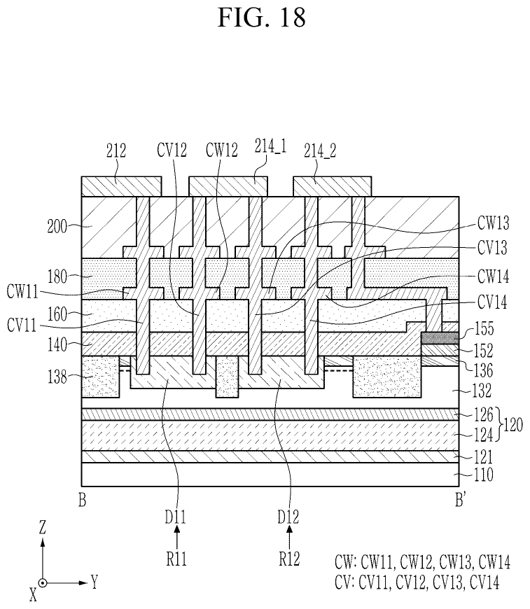

Referring to FIG. 18, the first connection via CV11 and the second connection via CV12 of the semiconductor device are connected to the first doping region D11, and the third connection via CV13 and the fourth connection via CV14 may be connected to the second doping region D12.

In some implementations, an isolation structure 138 may be further positioned between the second connection via CV12 and the third connection via CV13. The first doping region D11 and the second doping region D12 may be spaced and insulated by the isolation structure 138. An isolation structure 138 may be positioned between the first doping region D11 and the second doping region D12. In some implementations, the lower surface of the isolation structure 138 may be located at the same or lower level than the lower surfaces of the first doping region D11 and the second doping region D12. For example, after the first doping region D11 and the second doping region D12 are formed integrally, they may be separated into the first doping region D11 and the second doping region D12 as the isolation structure 138 is formed, but the fabrication is not limited to this. In some cases, the first doping region D11 and the second doping region D12 are formed separately, and the isolation structure 138 may be formed between the first doping region D11 and the second doping region D12.

In some implementations, the first resistor R11 may be composed of a first doping region D11 located between the first connection via CV11 and the second connection via CV12. The first resistor R11 may be connected between the first connection via CV11 and the second connection via CV12. By being connected between the first connection via CV11 and the second connection via CV12, the first resistor R11 may be connected between the gate pad 212 and the first gate runner 214_1.

In some implementations, the second resistor R12 may consist of a second doping region D12 located between the third connection via CV13 and the fourth connection via CV14. The second resistor R12 may be connected between the third connection via CV13 and the fourth connection via CV14. By being connected between the third connection via CV13 and the fourth connection via CV14, the second resistor R12 may be connected between the first gate runner 214_1 and the second gate runner 214_2.

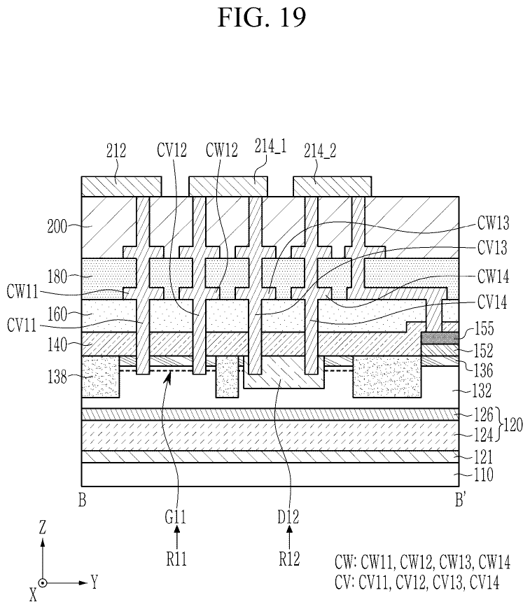

Referring to FIG. 19, the first connection via CV11 and the second connection via CV12 of the semiconductor device may be connected to the channel layer 132. The first connection via CV11 and the second connection via CV12 may be connected to the two-dimensional electron gas G11 occurring inside the channel layer 132. In some implementations, the third connection via CV13 and the fourth connection via CV14 may be connected to the second doping region D12.

In some implementations, an isolation structure 138 may be further positioned between the second connection via CV2 and the third connection via CV3. By the isolation structure 138, the two-dimensional electron gas G1 and the second doping region D2 may be spaced apart and insulated.

In some implementations, the first resistor R11 may be composed of a two-dimensional electron gas G11 occurring inside the channel layer 132 located between the first connection via CV11 and the second connection via CV12. The first resistor R11 may be connected between the first connection via CV11 and the second connection via CV12. By being connected between the first connection via CV11 and the second connection via CV12, the first resistor R11 may be connected between the gate pad 212 and the first gate runner 214_1.

In some implementations, the second resistor R12 may be composed of a second doping region D12 located between the third connection via CV13 and the fourth connection via CV14. The second resistor R12 may be connected between the third connection via CV13 and the fourth connection via CV14. By being connected between the third connection via CV13 and the fourth connection via CV14, the second resistor R12 may be connected between the first gate runner 214_1 and the second gate runner 214_2.

In the aforementioned example, the first resistor R11 is depicted as being composed of a two-dimensional electron gas and the second resistor R12 as being composed of a doping region, but it is not limited to this. For example, the first resistor R11 may be composed of a doping region and the second resistor R12 may be composed of a two-dimensional electron gas. For example, the first resistor R11 may be composed of a first doping region D11 located between the first connection via CV11 and the second connection via CV12, and the second resistor R12 may be composed of a two-dimensional electron gas G12 occurring in the channel layer 132 located between the third connection via CV13 and the fourth connection via CV14. The first connection via CV11 and the second connection via CV12 may be connected to the first doping region D11, and the third connection via CV13 and the fourth connection via CV14 may be connected to the channel layer 132. The third connection via CV13 and the fourth connection via CV14 may be connected to the two-dimensional electron gas G12 located in the channel layer 132. An isolation structure 138 may be positioned between the second connection via CV12 and the third connection via CV13. By the isolation structure 138, the first doping region D11 and the two-dimensional electron gas G12 may be spaced apart and insulated.

FIGS. 17, 18, and 19 show a resistor connected between the gate pad 212 and the first gate runner 214_1, and a resistor connected between the first gate runner 214_1 and the second gate runner 214_2, but the resistor configuration is not limited to this. For example, the semiconductor device may further include a resistor connected between the second gate runner 214_2 and the gate electrode 155. In this case, the resistor connected between the gate pad 212 and the first gate runner 214_1 may be omitted.

in the description provided for FIGS. 5 and 6 may be applied to the examples shown in FIGS. 17, 18, and 19. According to this, the resistance of each of the first resistor R11 and the second resistor R12 may be adjusted by controlling the length of at least a portion of the connection wiring CW that connects at least one of the gate pad 212, gate runner 214, and gate electrode 155 to each of the first resistor R11 and the second resistor R12 via the shortest path. Additionally, the resistance of each of the first resistor R11 and the second resistor R12 may also be adjusted by controlling the number of connection vias CV that connect at least one of the gate pad 212, gate runner 214, and gate electrode 155 to each of the first resistor R11 and the second resistor R12 via the shortest path.

The example shown in FIG. 7 may be merged with the example shown in FIGS. 17, 18, and 19. According to this, one or each of the first resistor R11 and the second resistor R12 may be made of a two-dimensional electron gas and a doping region. For example, the two-dimensional electron gas and doping region included in each of the first resistor R11 and the second resistor R12 may be connected in series or in parallel.

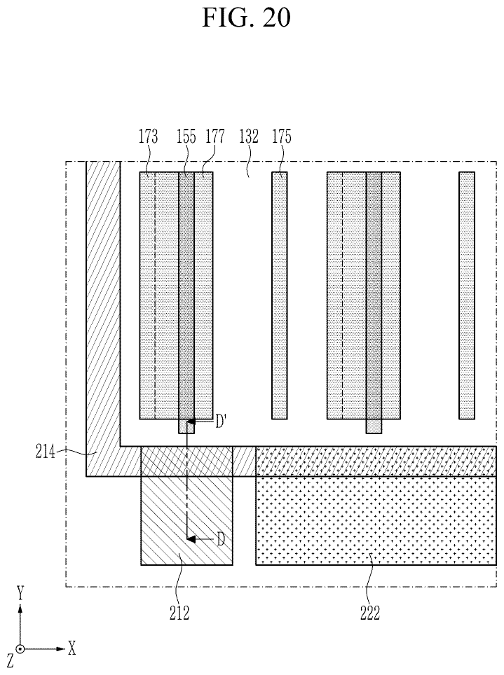

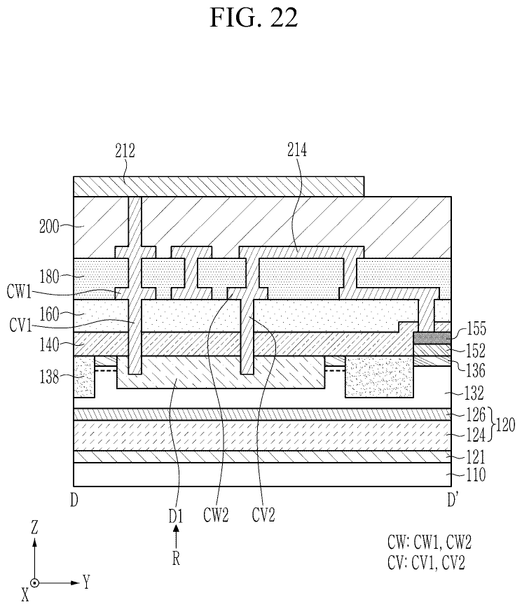

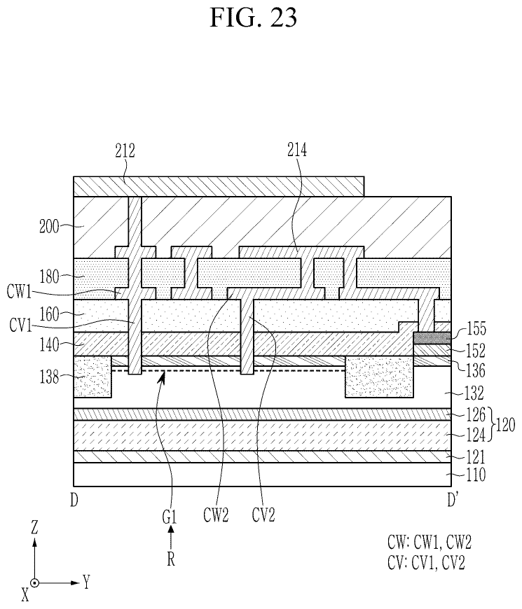

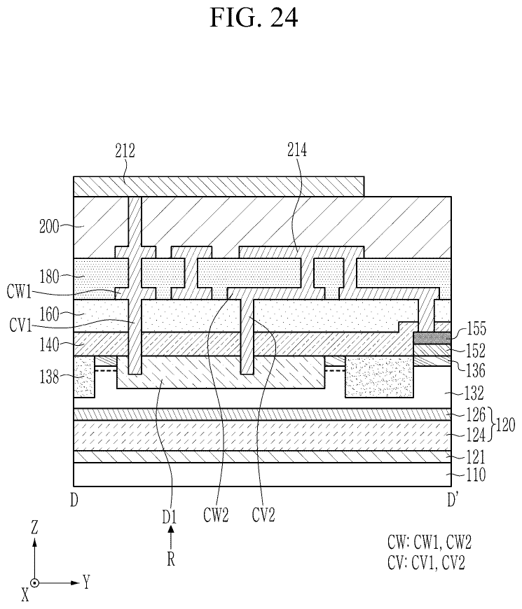

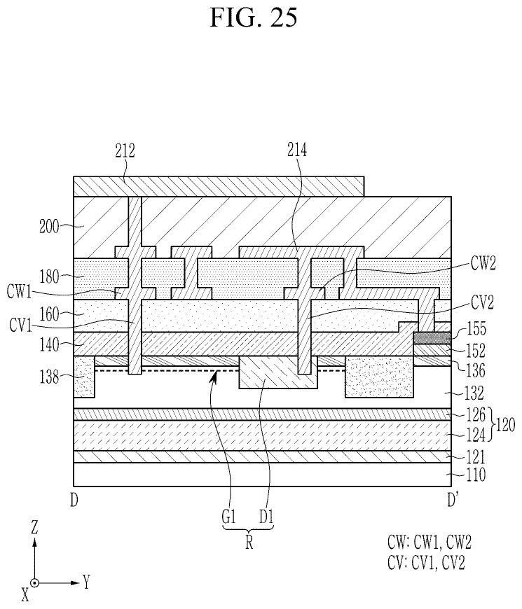

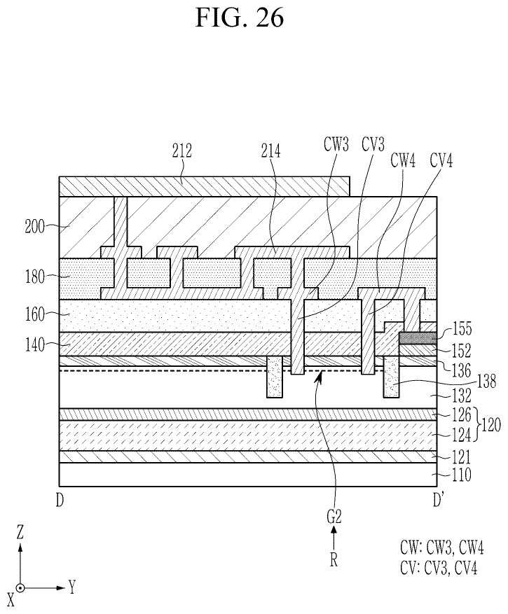

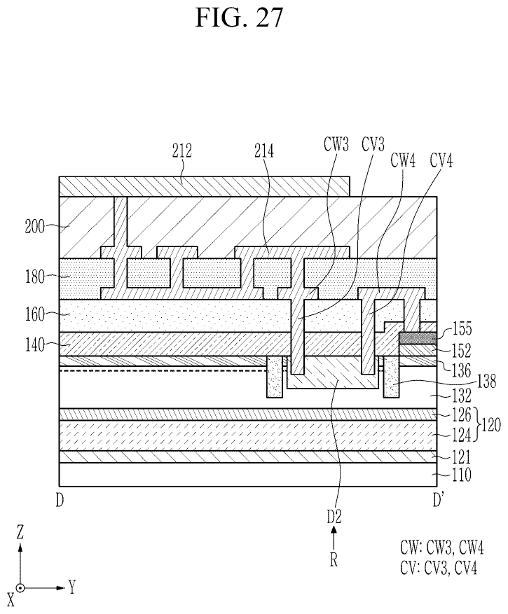

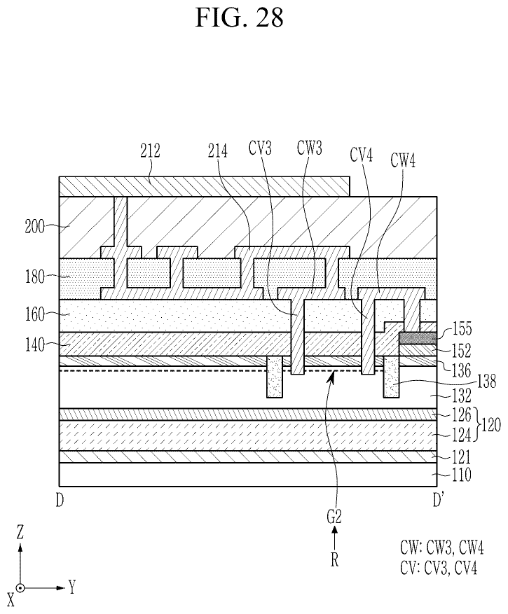

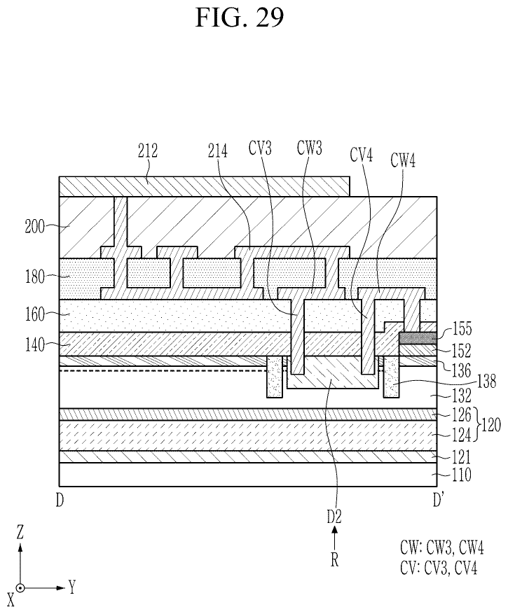

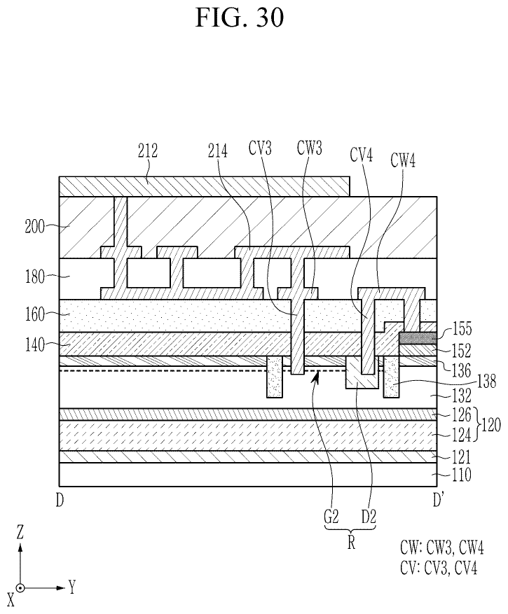

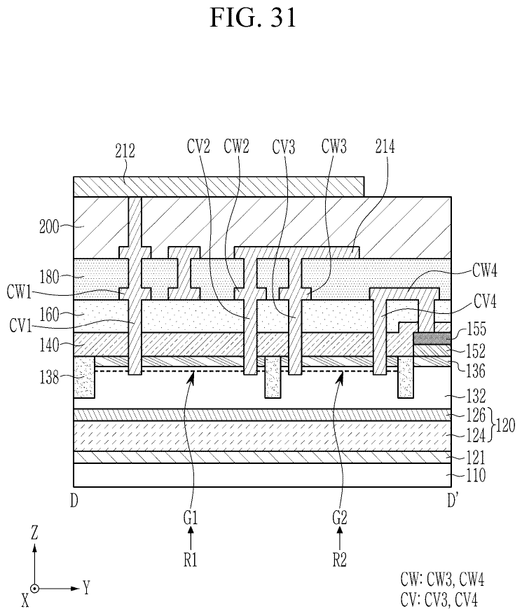

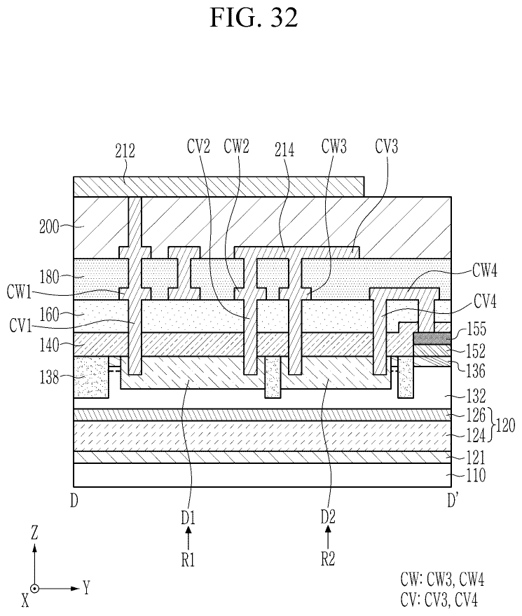

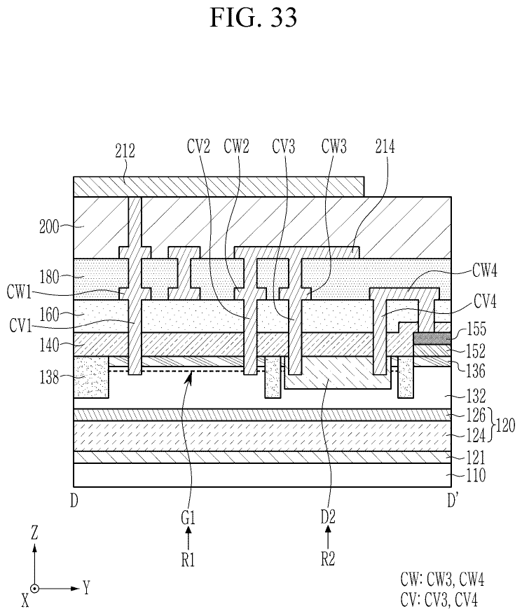

Below, with reference to FIGS. 20 to 33, examples in which the gate pad and the gate runner of the semiconductor device are located on different layers will be described, as modifications of the examples of FIGS. 3 to 15.

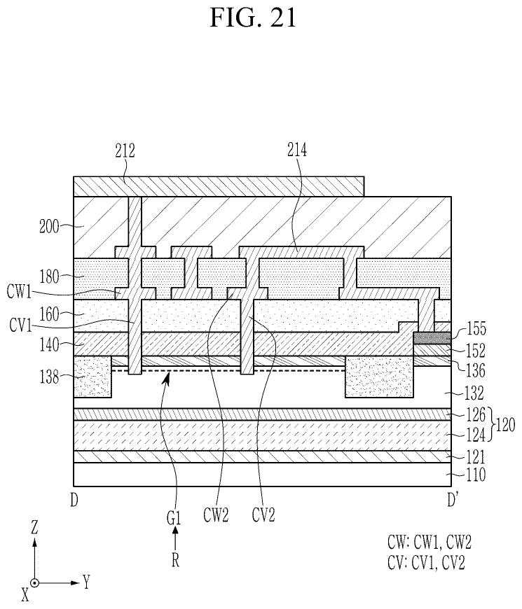

FIG. 20 is a plan view of an example of a semiconductor device. FIGS. 21, 22, 23, 24, 25, 26, 27, 28, 29, 30, 31, 32, and 33 are cross-sectional views of examples of semiconductor devices taken along line D-D′ of FIG. 20. For convenience and clarity of illustration, FIG. 20 only shows the source electrode 173 and field dispersion layer 177, drain electrode 175, gate electrode 155, gate pad 212, gate runner 214, and source pad 222 located on the channel layer 132, while other components are omitted.

The examples shown in FIGS. 21, 22, 23, 24, 25, 26, 27, 28, 29, 30, 31, 32, and 33 differ only or primarily in the positional relationship of the gate pad 212 and gate runner 214 compared to the examples shown in FIGS. 3, 4, 5, 6, 7, 8, 9, 10, 11, 12, 13, 14, and 15, while the remaining components may be the same or similar. Accordingly, the description of each example shown in FIGS. 3, 4, 5, 6, 7, 8, 9, 10, 11, 12, 13, 14, and 15 may be applied identically or similarly to the description for each example shown in FIGS. 21, 22, 23, 24, 25, 26, 27, 28, 29, 30, 31, 32, and 33. The following explanation will focus on the differences, omitting redundant descriptions.

Referring to FIGS. 20 to 33, the semiconductor device may include a gate pad 212 and a gate runner 214 located on different layers. The gate runner 214 may be positioned on a layer adjacent to the upper surface of the substrate 110 compared to the gate pad 212. For example, the gate pad 212 is located on the fourth protective layer 200, which is the uppermost protective layer among the plurality of protective layers 140, 160, 180, 200, and the gate runner 214 may be located between the first protective layer 140, which is the lowermost protective layer, and the fourth protective layer 200, which is the uppermost protective layer. For example, the gate runner 214 may be positioned on the third protective layer 180, but it is not limited to this. As another example, the gate runner 214 may also be located on the first protective layer 140 or the second protective layer 160.

In some implementations, the gate pad 212 and the gate runner 214 may overlap in a third direction Z perpendicular to the upper surface of the substrate 110. As the gate pad 212 and the gate runner 214 overlap in the third direction Z, the size of the semiconductor device may be reduced.

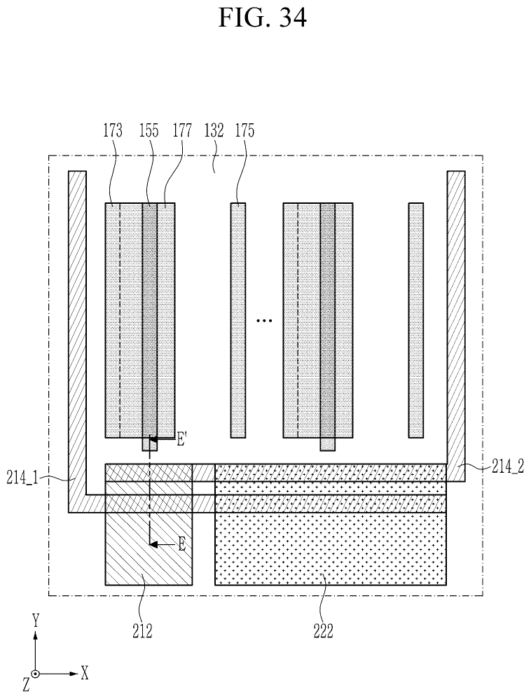

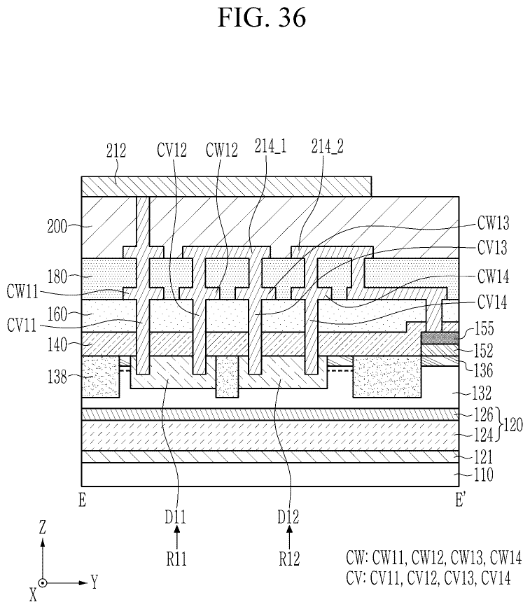

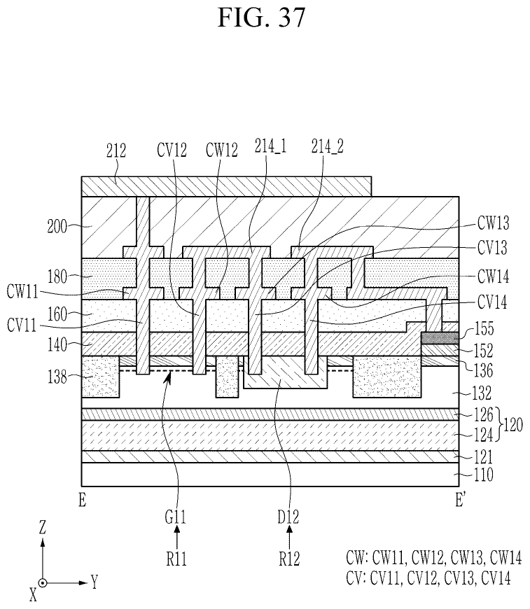

Below, with reference to FIGS. 34 to 37, description will be given of examples in which the gate pad and the gate runner of the semiconductor device described with respect to FIGS. 16 to 19 are located on different layers.

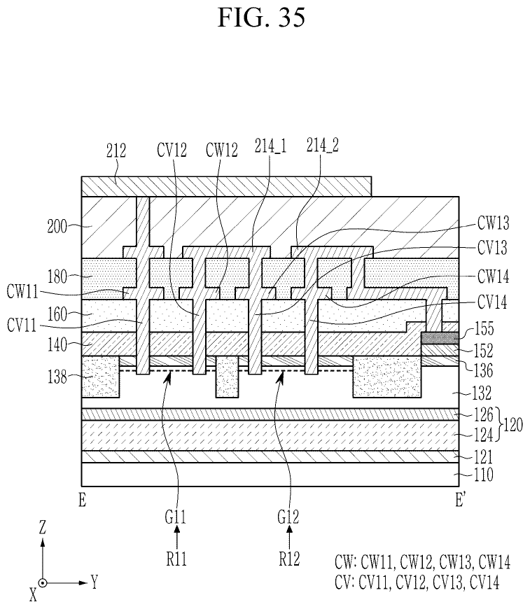

FIG. 34 is a plan view of an example of a semiconductor device. FIGS. 35, 36, and 37 are cross-sectional views of examples of semiconductor devices taken along line E-E′ of FIG. 34. For convenience and clarity of illustration, FIG. 34 only illustrates the source electrode 173 and field dispersion layer 177, drain electrode 175, gate electrode 155, gate pad 212, gate runner 214, and source pad 222 located on the channel layer 132, while other components are omitted.

The examples shown in FIGS. 35, 36, and 37 differ only or primarily from the examples shown in FIGS. 17, 18, and 19 in terms of the positional relationship between the gate pad 212 and the gate runner 214, while the remaining components may be the same or similar. Accordingly, the description for each example shown in FIGS. 17, 18, and 19 may be applied identically or similarly to each example shown in FIGS. 35, 36, and 37.

The description for the gate pad 212 and gate runner 214 of the examples shown in FIGS. 20 to 33 may be applied identically or similarly to the gate pad 212 and gate runner 214 of the examples shown in FIGS. 34 to 37.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although examples have been described in detail above, the scope of the present disclosure is not limited thereto, and various modifications and improvements made by those skilled in the art also fall within the scope of the present disclosure.

What is claimed is:

1. A semiconductor device comprising:
a substrate;
a channel layer on the substrate;
a barrier layer on the channel layer;
a gate electrode on the barrier layer;
a source electrode and a drain electrode on opposite lateral sides of the gate electrode and electrically connected to the channel layer;
a gate runner;
a gate pad; and
a resistor in the channel layer, wherein the resistor is electrically connected between the gate pad and the gate runner, or between the gate runner and the gate electrode.

2. The semiconductor device of claim 1, wherein the resistor is electrically connected between the gate pad and the gate runner, and wherein the semiconductor device comprises:
a first connection wiring and a first connection via electrically connecting the gate pad and the resistor; and
a second connection wiring and a second connection via electrically connecting the gate runner and the resistor.

3. The semiconductor device of claim 2, wherein the first connection via and the second connection via are electrically connected to the channel layer, and
wherein the resistor comprises a two-dimensional electron gas in the channel layer, wherein the two-dimensional electron gas is between the first connection via and the second connection via.

4. The semiconductor device of claim 2, comprising a doping region in the channel layer between the first connection via and the second connection via,
wherein the first connection via and the second connection via are electrically connected to the doping region, and
wherein the resistor comprises the doping region.

5. The semiconductor device of claim 2, comprising a doping region in the channel layer between the first connection via and the second connection via,
wherein one of the first connection via or the second connection via is electrically connected to the channel layer, and the other one of the first connection via or the second connection via is electrically connected to the doping region, and
wherein the resistor comprises:
a two-dimensional electron gas in the channel layer between the first connection via and the second connection via, and
the doping region.

6. The semiconductor device of claim 1, wherein the resistor is electrically connected between the gate runner and the gate electrode, and wherein the semiconductor device comprises:
a third connection wiring and a third connection via electrically connecting the gate runner and the resistor; and
a fourth connection wiring and a fourth connection via electrically connecting the gate electrode and the resistor.

7. The semiconductor device of claim 6, wherein the third connection via and the fourth connection via are electrically connected to the channel layer, and
wherein the resistor comprises a two-dimensional electron gas in the channel layer, wherein the two-dimensional electron gas is between the third connection via and the fourth connection via.

8. The semiconductor device of claim 6, comprising a doping region in the channel layer between the third connection via and the fourth connection via,
wherein the third connection via and the fourth connection via are electrically connected to the doping region, and
wherein the resistor comprises the doping region.

9. The semiconductor device of claim 6, comprising a doping region in the channel layer between the third connection via and the fourth connection via,
wherein one of the third connection via or the fourth connection via is electrically connected to the channel layer, and the other one of the third connection via or the fourth connection via is electrically connected to the doping region, and
wherein the resistor comprises:
a two-dimensional electron gas in the channel layer between the third connection via and the fourth connection via, and
the doping region.

10. The semiconductor device of claim 1, wherein the resistor comprises a first resistor electrically connected between the gate pad and the gate runner, wherein the semiconductor device comprises a second resistor electrically connected between the gate runner and the gate electrode, and
wherein the semiconductor device comprises:
a first connection wiring and a first connection via electrically connecting the gate pad and the first resistor;
a second connection wiring and a second connection via electrically connecting the gate runner and the first resistor;
a third connection wiring and a third connection via electrically connecting the gate runner and the second resistor; and
a fourth connection wiring and a fourth connection via electrically connecting the gate electrode and the second resistor.

11. The semiconductor device of claim 10, wherein the first connection via, the second connection via, the third connection via, and the fourth connection via are electrically connected to the channel layer,
wherein the first resistor comprises a first two-dimensional electron gas in the channel layer between the first connection via and the second connection via, and
wherein the second resistor comprises a second two-dimensional electron gas in the channel layer between the third connection via and the fourth connection via.

12. The semiconductor device of claim 10, comprising a doping region in the channel layer,
wherein the first connection via, the second connection via, the third connection via, and the fourth connection via are electrically connected to the doping region,
wherein the first resistor comprises a portion of the doping region between the first connection via and the second connection via, and
wherein the second resistor comprises a portion of the doping region between the third connection via and the fourth connection via.

13. The semiconductor device of claim 10, comprising a doping region in the channel layer,
wherein one of the first resistor and the second resistor comprises a two-dimensional electron gas in the channel layer, and the other one of the first resistor or the second resistor comprises the doping region.

14. The semiconductor device of claim 1, wherein the gate runner includes a first gate runner portion and a second gate runner portion, and
wherein the semiconductor device comprises a second resistor electrically connected between the first gate runner portion and the second gate runner portion.

15. The semiconductor device of claim 1,
wherein the gate pad and the gate runner are overlapping along a direction perpendicular to a surface of the substrate on which the gate pad and the gate runner are arranged.

16. A semiconductor device comprising:
a substrate;
a channel layer on the substrate;
a barrier layer on the channel layer;
a gate electrode on the barrier layer;
a source electrode and drain electrode on opposite lateral sides of the gate electrode and electrically connected to the channel layer;
a gate runner;
a gate pad; and
at least one resistor comprising a two-dimensional electron gas, wherein the two-dimensional electron gas is in the channel layer, and
wherein the at least one resistor is electrically connected between:
(i) the gate pad and the gate runner,
(ii) the gate runner and the gate electrode, or
(i) and (ii).

17. The semiconductor device of claim 16, comprising:
a first connection wiring electrically connected to the gate pad, and a first connection via electrically connecting the first connection wiring and the channel layer; and
a second connection wiring electrically connected to the gate runner, and a second connection via electrically connecting the second connection wiring to the channel layer,
wherein the two-dimensional electron gas is between the first connection via and the second connection via.

18. The semiconductor device of claim 16, comprising:
a third connection wiring electrically connected to the gate runner, and a third connection via electrically connecting the third connection wiring and the channel layer; and
a fourth connection wiring electrically connected to the gate electrode, and a fourth connection via electrically connecting the fourth connection wiring and the channel layer; and
wherein the two-dimensional electron gas is between the third connection via and the fourth connection via.

19. The semiconductor device of claim 16, comprising a doping region in the channel layer,
wherein the at least one resistor comprises the two-dimensional electron gas and the doping region.

20. A semiconductor device comprising:
a substrate;
a high electron mobility transistor on the substrate;
a connection wiring on the high electron mobility transistor;
a gate runner electrically connected to the high electron mobility transistor through the connection wiring;
a gate pad electrically connected to the high electron mobility transistor through the gate runner; and
a resistor electrically connected between the gate pad and the gate runner, or between the gate runner and the high electron mobility transistor,
wherein the high electron mobility transistor includes:
a channel layer on the substrate,
a barrier layer on the channel layer,
a gate electrode on the barrier layer, and
a source electrode and a drain electrode on opposite lateral sides of the gate electrode and electrically connected to the channel layer,
wherein the resistor is in the channel layer.
